(19) United States
(12) Patent Application Publication
(10) Pub. No.: US 2007/0252659 A1
(43) Pub. Date: Nov. 1, 2007

(54) Filter Circuit, Differential Transmission System Having Same, and Power Supply

(76) Inventors: Hiroshi Suenaga, Osaka (JP); Osamu Shibata, Hyogo (JP); Yoshiyuki Saito, Osaka (JP); Noboru Katta, Kanagawa (JP); Yuji Mizuguchi, Osaka (JP)

Correspondence Address: WENDEROTH, LIND & PONACK L.L.P., 2033 K. STREET, NW, SUITE 800, WASHINGTON, DC, 20006, US

(21) Appl. No.: 11/664,129

(22) PCT Filed: Aug. 1, 2005
(86) PCT No.: PCT/JP05/14040

§ 371 Date: Mar. 29, 2007

(30) Foreign Application Priority Data
Oct. 14, 2004 (JP) 2004-299851
Jan. 12, 2005 (JP) 2005-004777

(51) Int. Cl. H03H 7/38

(52) U.S. Cl. 333/32

(57) ABSTRACT

In a filter circuit (1), a common mode choke (2) and a normal mode choke (3) have extremely high and low impedances, respectively, for common mode signals received through two input terminals (1a and 1b). The chokes have the opposite impedance characteristics for differential signals. In particular, the difference in impedance is large. Furthermore, the normal mode choke (3) is installed as a previous stage of the common mode choke (2). Accordingly, common mode noises which enter the two input terminals (1a and 1b) penetrate the normal mode choke (3), but neither penetrate the common mode choke (2) nor are reflected from the common mode choke (2). In particular, common mode currents flow through the normal mode choke (3) but do not flow through the common mode choke (2).

### TECHNICAL FIELD

The present invention relates to a differential transmission system that allows communications between electronic appliances using a differential transmission scheme, and a power supply that converts electric power supplied by an external power supply such as a commercial AC power supply, and in particular relates to filter circuits that are installed in the system and the power supply.

### BACKGROUND OF THE INVENTION

Processing speeds of general electronic appliances have been still increasing in order to satisfy demand for multifunctionality and higher performance. This requires further increases in the speed of communications between electronic appliances. Serial transmission has advantages over parallel transmission in the further increases in the speed of communications. Accordingly, serial transmission schemes are widely adopted by various standards, such as USB, EEEE 1394, LVDS, DVI, HDMI, serial ATA, PCI express, in recent years. In particular, the operating frequencies of car-mounted electronic devices (i.e. electronic control units (ECU)) such as a car navigation system and an operation support system, have been remarkably increased. Accordingly, a controller area network (CAN), a serial communication protocol, has been substantially standardized for in-car LANs.

In general, differential transmission schemes are adopted in high-speed serial transmission. The differential transmission schemes refer to schemes to transmit a series of serial data by using two signals with opposite phases (differential signals or normal mode signals). In particular, both transmission lines for the differential signals run in parallel. A receiving device (differential receiver) reads serial data from the difference between the two differential signals. Thereby, the differential transmission scheme can use differential signals of half the amplitude of a single signal used by a single-ended transmission scheme, which is a scheme to transmit serial data expressed by the single signal. Accordingly, general differential signals rise and fall faster than the single signal, or in other words, lower slew rates are acceptable. Thus, the differential transmission scheme has advantages in further increases in the speed of signal transmission.

In addition, the differential transmission scheme has advantages in the reduction of electromagnetic interference (EMI). For example, because the lines of two differential signals (differential lines) run in parallel, electromagnetic waves emitted from both the differential lines cancel each other out in the surrounding area. Accordingly, EMI radiation is extremely weak in the differential transmission scheme. Conversely, when the differential lines receive electromagnetic waves from surrounding electronic appliances and the like, in-phase noises (common mode noises) occur in the two differential lines. However, the common mode noises in both the differential lines cancel each other out in the difference between the two differential signals. Thus, the differential transmission scheme is resistant to common mode noises caused by external EMI.

Differential transmission schemes are in particular common to various in-car LANs including CAN. In a car, the basic components thereof such as an engine and various electronic control units (ECU) (such as the motors which rotate door mirrors) provide noises for an in-car LAN. Furthermore, the car runs in various environments, and exposes the in-car LAN to various types of external electromagnetic radiation. Accordingly, the in-car LAN needs the advantages of a differential transmission scheme that produces little or no noises and that is resistant to noises.

Filter circuits are installed in general transmitter-receivers that use the differential transmission scheme (differential transmission and reception devices), and reliably suppress adverse effects caused by common mode noises. The filter circuit includes a common mode choke, and by using it, reduces the level of the common mode noises less than the upper limit of the input range of the differential receiver, thereby preventing the differential receiver from malfunction and destruction.

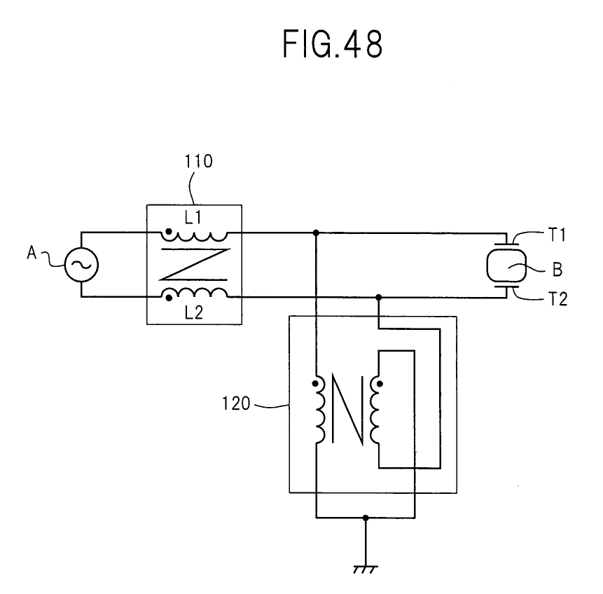

Conventional filter circuits include one having a common mode choke and a normal mode choke of the following stage, for example, the filter circuit shown in FIG. 48 (see, for example, reference 1). This filter circuit is installed in a device that heats a cell B inside a living body by using high frequency electromagnetic waves. The cell B inside the living body is placed between two electrodes T1 and T2. A high frequency generator A varies both voltages of the electrodes T1 and T2 at a high frequency. At that time, for the in-phase components (i.e., common mode noises) of the voltage variation of both the electrodes T1 and T2, the common mode choke 110 and the normal mode choke 120 have high and low impedances, respectively. Accordingly, little in-phase currents (common mode currents) flow through the inductors L1 and L2 in the common mode choke 110 at the previous stage. Furthermore, most of the reduced common mode currents flows through the normal mode choke 120 at the following stage. Thus, common mode currents do not flow between the pair of the electrodes T1 and T2 and the cell B inside the living body. In other words, leakage currents are prevented except those flowing between the cell B and the electrode T1 or T2.

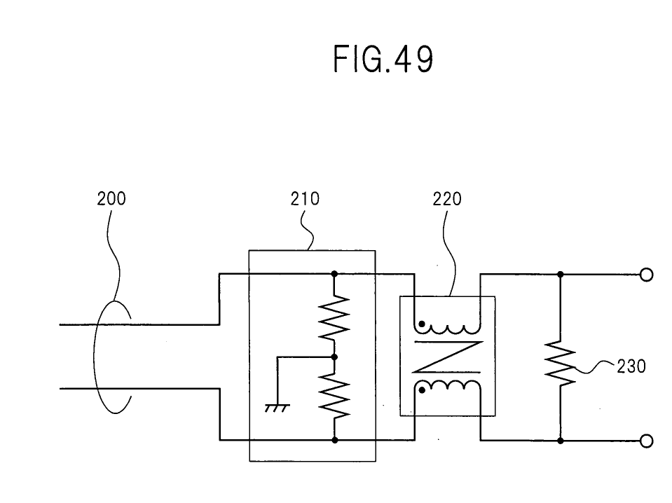

Another conventional filter circuit includes a terminator element, a common mode choke, and a resistance element, such as the one shown in FIG. 49 (see, for example, reference 2). The terminator element 210 comprises two equivalent resistance elements that are connected in series between the terminals of two differential lines 200, and have a grounded node therebetween. The resistance element 230 is connected between the output terminals of the common mode choke 220.

The impedance of the common mode choke 220 is extremely high for common mode signals that propagate the differential lines 200. Accordingly, the common mode impedance of the terminator element 210 is adjusted to match the common mode impedance of the differential lines 200. On the other hand, the impedance of the common mode choke 220 is extremely low for the differential signals that propagate the differential lines 200. Accordingly, the composition of the differential impedance of the terminator element 210 and the impedance of the resistance element 230 is adjusted to match the differential impedance of the differential lines 200. Thus, the common mode noises reflected at the common mode choke 220 are suppressed, and distortion and attenuation of the differential signals caused by the terminator element 210 and the common mode choke 220 are avoided. Furthermore, common mode currents flowing through the differential lines 200 are divided into two branches; one flows through the terminator element 210 and the other flows through the common mode choke 220. Accordingly, a reduced amount of the common mode currents flow through the common mode choke 220, and therefore, the core of the common mode choke 220 is hardly magnetized to saturation and overcurrents do not flow in the following stages. Therefore, this filter circuit maintains high reliability.

EMI noise reduction is important for not only for communications systems using the differential transmission schemes (differential transmission systems) but also power supplies that convert external AC power to suitable electric power. The power supplies are connected to an external AC power supply, such as commercial AC power supplies, and then convert AC voltages to DC voltages preferably by using switching power supplies, or alternatively, improve the power factor of the electric power supplied from the external AC power supplies. Furthermore, EMI noise reduction is necessary when the power supplies are used in power line communication (PLC). The above-described filter circuit is effective at reducing EMI noises for such power supplies in a similar manner to that of the differential transmission systems. The filter circuit cuts off the common mode noises that occur in the external power lines from the power supplies, thereby stabilizing the electric power sent to the following steps. The filter circuit further cuts off, for example, the common mode noises caused by switching in the power supplies, or cuts off the common mode noises received from the following steps, from the external power lines. This suppresses EMI radiation caused by the power supplies.

Reference 1: Japan Published Patent Application No. 1984-207148

Reference 2: Japan Published Patent Application No. 2002-261842

### DISCLOSURE OF INVENTION

### Object of the Invention

Further increases in the speed of serial transmission requires a higher quality of serial signals and greater suppression of EMI radiation to the surroundings, by more effectively suppressing the occurrences of common mode noises in differential lines. On the other hand, further improvements in reliability of power supply require a higher quality of converted electric power and greater suppression of EMI radiation to the surroundings, by more effectively suppressing the occurrences of common mode noises in power lines. Thus, in either of the differential transmission systems and power supplies, it is desirable to further improve filter circuits having an effect of suppressing common mode noises.

However, in the conventional filter circuit shown in FIG. 48, most of the common mode noises sent out from a high-frequency generator A are reflected at the common mode choke 110, and their electric power is dissipated into the surroundings as electromagnetic radiation from the cable between the high-frequency generator A and the common mode choke 110. In other words, this filter circuit is difficult to further improve the effect thereof of suppressing EMI radiation. Furthermore, when common mode currents become excessive, the core of the common mode choke 110 is magnetized to saturation, and then the common mode choke 110 may lose the effect of suppressing common mode noises. In other words, in this filter circuit, it is difficult to further improve the effect of suppressing common mode noises while maintaining the compact core of the common mode choke 110.

In the conventional filter circuit shown in FIG. 49, the terminator element 210 reduces the reflection of common mode noises at the common mode choke 220, and accordingly, faint EMI radiation is emitted from the filter circuit. Furthermore, since common mode currents branch into the terminator element 210 and the common mode choke 220, the core of the common mode choke 220 is hardly magnetized to saturation. On the other hand, for differential signals, the total impedance of the terminator element 210 and the resistance element 230 matches the differential impedance of the differential lines 200. Accordingly, the differential signals sent out from the filter circuit undergo little distortion and attenuation.

However, the differential impedance of the terminator element 210 depends on the common mode impedance thereof (i.e., the resistance values of the resistance elements), and moreover the difference between both impedances is small (the differential impedance is about four times the common mode impedance). Accordingly, it is difficult to further raise the differential impedance of the terminator element 210 under the condition in which common mode impedances are to be matched between the terminator element 210 and the differential lines. Therefore, it is difficult to further suppress distortion and attenuation of the differential signals caused by the terminator element 210 or the resistance element 230 while sufficiently suppressing the reflection of common mode noises by the common mode choke 220.

Alternatively, the resistance element 230 must be placed at stages next to the common mode choke 220 in order to suppress distortion and attenuation of the differential signals caused by the common mode choke 220. In that case, the path length between the terminator element 210 and the resistance element 230 cannot be reduced below a certain extent. Accordingly, when the frequency of the differential signal further rises and the wavelength thereof is reduced to a negligible extent with respect to the path length between the terminator element 210 and the resistance element 230, it is difficult to match the total impedance of the terminator element 210 and the resistance element 230 to the differential impedance of the differential lines with high precision. Thus, it is difficult to further suppress distortion and attenuation of the differential signals in higher frequency bands.

An object of the present invention is to provide a filter circuit that can separate differential signals and common mode signals without causing excessive distortion and attenuation of the differential signals and without reflecting the common mode signals, in sufficiently large frequency bands, and in addition, and that can reliably avoid magnetic saturation of the core of the common mode choke caused by common mode currents.

### Means to Attain the Object of the Invention

A filter circuit according to the present invention comprises:

a first input terminal and a second input terminal;

a first output terminal, a second output terminal, a third output terminal, and a fourth output terminal;

a common mode choke including
a first inductor that is connected between the first input terminal and the first output terminal, and
a second inductor that is magnetically coupled to the first inductor and connected between the second input terminal and the second output terminal in the same polarity as the polarity of the first inductor; and

a normal mode choke including
a third inductor that is connected between the first input terminal and the third output terminal, and
a fourth inductor that is magnetically coupled to the third inductor and connected between the second input terminal and the fourth output terminal in the polarity opposite to the polarity of the third inductor.

Here, the first to fourth inductors are preferably multilayer inductors or thin film inductors. In that case, the common mode choke and the normal mode choke are incorporated on the same chip, and accordingly, this filter circuit is extremely small.

Alternatively, each of the common mode choke and the normal mode choke may include a core and two coils that are wound around the core. In the normal mode choke, preferably, the two coils are wound around the core in the polarities where the magnetic fluxes induced by common mode currents cancel each other out. In other words, either of the directions of the two coils is the reversed direction of a winding in a bifilar or cancel coil. Accordingly, a shorter trace may be connected between the normal mode choke and the input or output terminals of the filter circuit. This facilitates miniaturization of the filter circuit. In the normal mode choke, the two coils may be wound in a bifilar or cancel form, in a similar manner to that of a general common mode choke. In that case, the polarity of the coupling of the third inductor to the input terminals is to be the reverse of the polarity of the coupling of the fourth inductor to the output terminals.

In the filter circuit of the present invention, the common mode choke has a sufficiently high impedance for common mode noises and a sufficiently low impedance for differential signals. Conversely, the normal mode choke has a sufficiently low impedance for common mode noises and a sufficiently high impedance for differential signals. In particular, the differences between the impedances are sufficiently large. Moreover, the normal mode choke is placed at the previous stage of the common mode choke, that is, the position nearer to the first and second input terminals than the common mode choke. Accordingly, of the signals received through the first and second input terminals, only the normal mode components are allowed to pass through the common mode choke, and only the common mode components are allowed to pass through the normal mode choke. Thus, the common mode noises received through the first and second input terminals are cut off from the first and second output terminals. Furthermore, since the common mode choke reflects little common mode noises, EMI radiation is reduced. In addition, since common mode currents hardly flow in the common mode choke, the core of the common mode choke is not magnetized to saturation. Therefore, the common mode choke has a higher degree of reliability.

Preferably, the above-described filter circuit according to the present invention further includes first and second impedance elements. The first impedance element is connected either between the third inductor and the third output terminal, or between the first input terminal and the third inductor, or both. The second impedance element is connected either between the fourth inductor and the fourth output terminal, or between the second input terminal and the fourth inductor, or both. Between differential lines and the filter circuit, the first and second impedance elements allow the impedance matching for common mode signals to be attained with a higher degree of precision, while keeping the precise impedance matching for differential signals. This further prevents common mode noises from the reflection by the common mode choke, and thereby, EMI radiation is reduced more greatly.

The above-described filter circuit according to the present invention preferably comprises a fifth output terminal and a sixth output terminal; and

a second normal mode choke including

a fifth inductor that is connected between the first output terminal and the fifth output terminal, and
a sixth inductor that is magnetically coupled to the fifth inductor and connected between the second output terminal and the sixth output terminal in the polarity opposite to the polarity of the fifth inductor.

Here, the fifth and sixth inductors are preferably multilayer inductors or thin film inductors. Alternatively, the second normal mode choke may include a core, and two coils that are wound around the core. In that case, either of the two coils may be preferably wound in the reversed direction of a wiring in a bifilar or cancel coil. Aside from this, the two coils may be wound in a bifilar or cancel form, in a similar manner to that of the above-described coils of the normal mode choke. In that case, the polarities of the coupling to the output terminals of the filter circuit are opposed to each other between the fifth and sixth inductors.

The second normal mode choke has a sufficiently low impedance for common mode noises. Accordingly, common mode noises received through the first and second output terminals are transmitted through the second normal mode choke to the fifth and sixth output terminals, but not to the common mode choke. In other words, common mode noises received through the first and second output terminals are cut off from the first and second input terminals. Moreover, the common mode choke hardly reflects common mode noises. This reduces EMI radiation.

In addition, the two normal mode chokes are placed in an arrangement symmetric with respect to the position of the common mode choke, and accordingly, the above-described filter circuit according to the present invention can effectively reduce common mode noises transmitted bidirectionally, that is, even if the filter circuit has input and output terminals connected to the other circuits in the reversed polarities.

Preferably, the above-described filter circuit according to the present invention further includes third and fourth impedance elements. The third impedance element is connected either between the fifth inductor and the fifth output terminal, or between the first output terminal and the fifth inductor, or both. The fourth impedance element is connected either between the sixth inductor and the sixth output terminal, or between the second output terminal and the sixth inductor, or both. Between the filter circuit and the other external circuits, the third and fourth impedance elements allow the impedance matching for common mode signals to be attained with a higher degree of precision, while keeping the precise impedance matching for differential signals, and thereby, EMI radiation is reduced more greatly.

A differential receiving device according to the present invention preferably comprises one of the above-described filter circuits according to the present invention and a differential receiver comprising a pair of input terminals that are connected to the first and second output terminals of the filter circuit, respectively. In this differential receiving device, particularly, the first and second input terminals are connected to external differential lines, and the third and fourth output terminals are maintained at a constant potential (preferably, ground potential). Accordingly, common mode noises transmitted in the differential lines are forwarded to the third and fourth output terminals, but not to the differential receiver. Moreover, the common mode noises are hardly reflected to the differential lines. Thus, the differential receiving device according to the present invention is resistant to common mode noises and can greatly reduce EMI radiation.

A differential transmitting device according to the present invention preferably comprises one of the above-described filter circuits according to the present invention and a differential driver comprising a pair of output terminals that are connected to the first and second input terminals of the filter circuit, respectively. In this differential transmitting device, particularly, the first and second output terminals are connected to external differential lines, and the third and fourth output terminals are maintained at a constant potential (preferably, ground potential). Accordingly, common mode noises sent out from the differential driver are forwarded to the third and fourth output terminals, but not to the differential lines. Moreover, the common mode noises are hardly reflected to the differential driver. Thus, the differential transmitting device according to the present invention is resistant to common mode noises and can greatly reduce EMI radiation.

The above-described filter circuit according to the present invention that comprises the second normal mode choke is preferably installed in a differential transmitting and receiving device. The differential transmitting and receiving device uses the first and second input terminals of the filter circuit as a first input/output terminal and a second input/output terminal, respectively, and uses the first and second output terminals as a third input/output terminal and a fourth input/output terminal, respectively. The first and second input/output terminals are connected to the pair of the input terminals of a differential receiver and the pair of the output terminals of a differential driver, and the third and fourth input/output terminals are connected to external differential lines. Moreover, the third to sixth output terminals of the filter circuit (hereinafter, renamed to first to fourth output terminals, respectively) are all maintained at a constant potential (preferably, ground potential). Accordingly, common mode noises sent out from the differential driver are forwarded through the normal mode choke to the first and second output terminals, but not to the differential lines. Furthermore, the common mode noises are hardly reflected to the differential driver and the differential receiver. Conversely, common mode noises transmitted in the differential lines are forwarded through the second normal mode choke to the third and fourth output terminals, but not to the differential receiver and the differential driver. Moreover, the common mode noises are hardly reflected to the differential lines. Thus, the differential transmitting and receiving device according to the present invention is resistant to common mode noises and can greatly reduce EMI radiation.

A power supply according to the present invention preferably comprises one of the above-described filter circuits according to the present invention and a power transducer comprising a pair of input terminals that are connected to the first and second output terminals of the filter circuit, respectively. In this power supply, particularly, the first and second input terminals are connected to external power lines, and the third and fourth output terminals are maintained at a constant potential (preferably, ground potential). Accordingly, common mode noises received from the power lines are forwarded to the third and fourth output terminals, but not to the power transducer. Moreover, the common mode noises are hardly reflected to the power lines. The power supply may be further equipped with the second normal mode choke, and thereby, common mode noises sent out from the power transducer and the other circuits of the following stages are cut off from the external power lines. Thus, the power supply according to the present invention is resistant to common mode noises and can greatly reduce EMI radiation.

### MERITS OF THE INVENTION

In the filter circuit according to the present invention, as described above, the normal mode components of the signals received at the first and second input terminals pass through the common mode choke, while the common mode components of the signals pass through the normal mode choke. In particular, common mode noises are not allowed to be transmitted to the first and second output terminals, and accordingly, they are not reflected toward the first and second input terminals. Thus, the filter circuit according to the present invention separates differential signals from common mode signals without excessive distortion and attenuation of the differential signals and without reflecting the common mode signals. In particular, common mode noises are eliminated from the differential signals without being reflected. Accordingly, EMI radiation caused by common mode noises is greatly reduced, and malfunctions and destructions of circuit elements are prevented from excessive common mode noises. Furthermore, the core of the common mode choke is not magnetized to saturation, since common mode currents pass through the normal mode choke but not through the common mode choke. As a result, the core of the filter circuit according to the present invention is easy to miniaturize, and higher reliability of the filter circuit is easy to attain.

The filter circuit according to the present invention has advantages over conventional filter circuits in, particularly, EMI reduction, common-mode noise immunity, and miniaturization. Accordingly, it is suitable for use in differential transmission systems installed in various serial interfaces such as USB, IEEE1394, LVDS, DVI, HDMI, serial ATA, and PCI express, particularly the differential transmission systems installed in in-car LAN and portable information apparatuses (mobile appliances), and for use in power supplies.

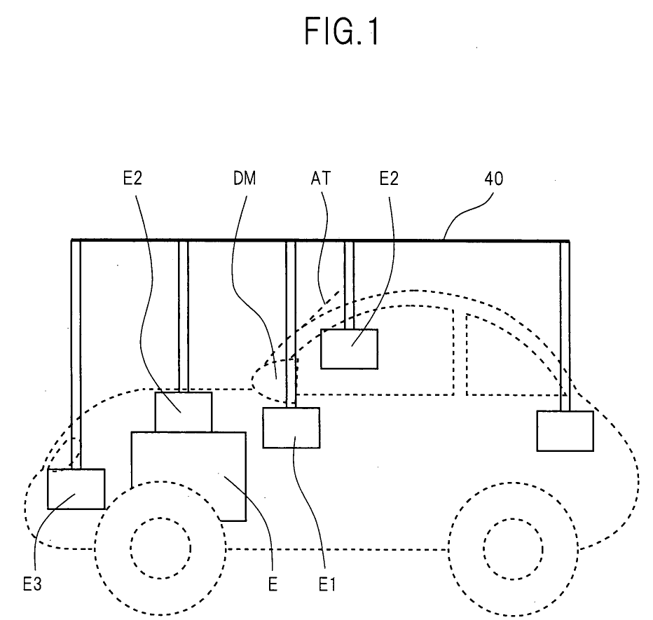

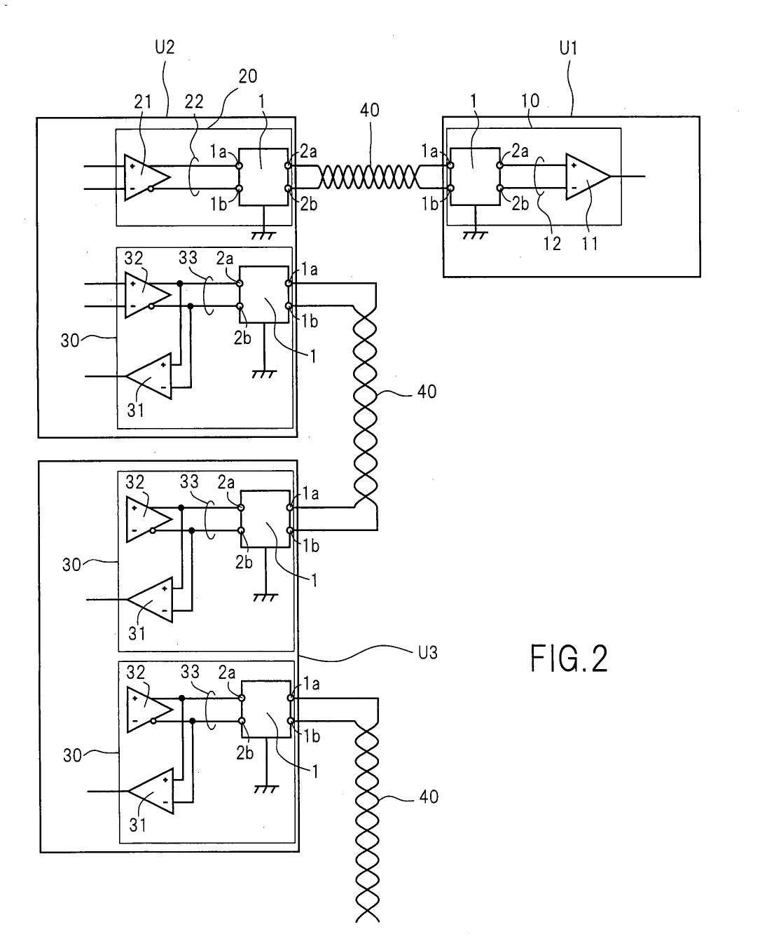

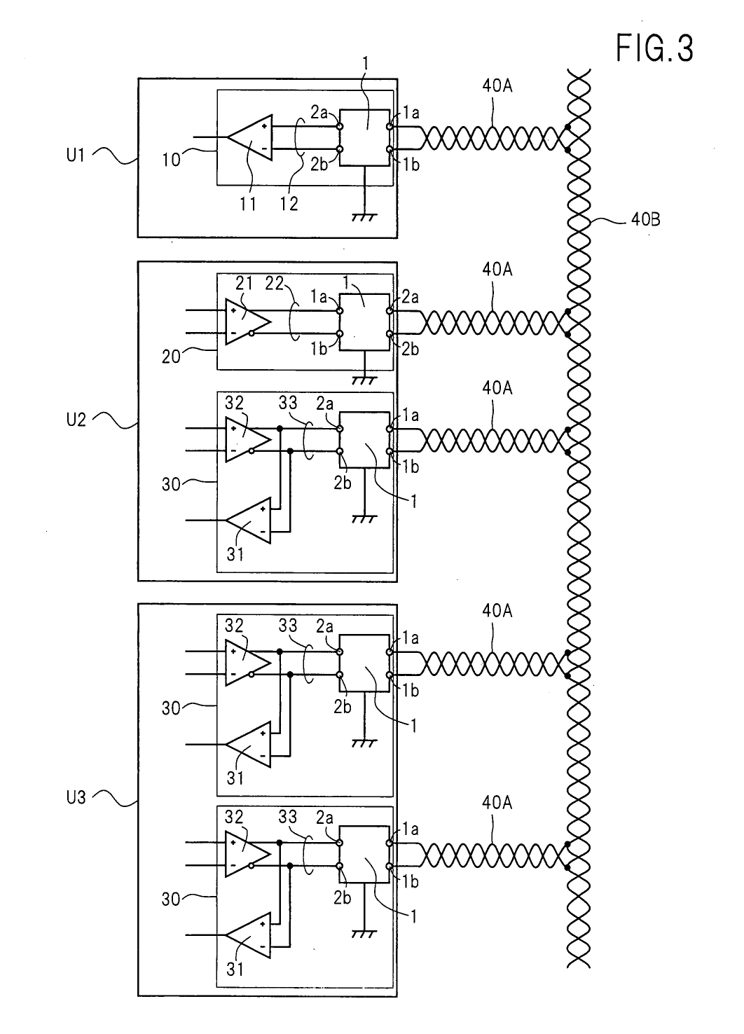

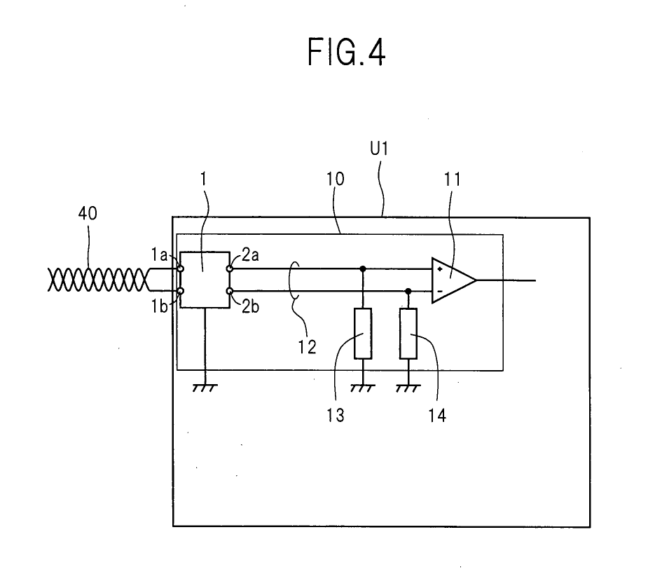

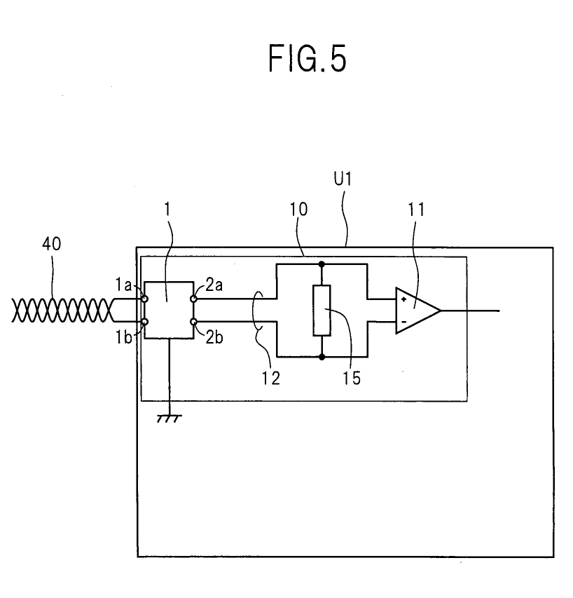

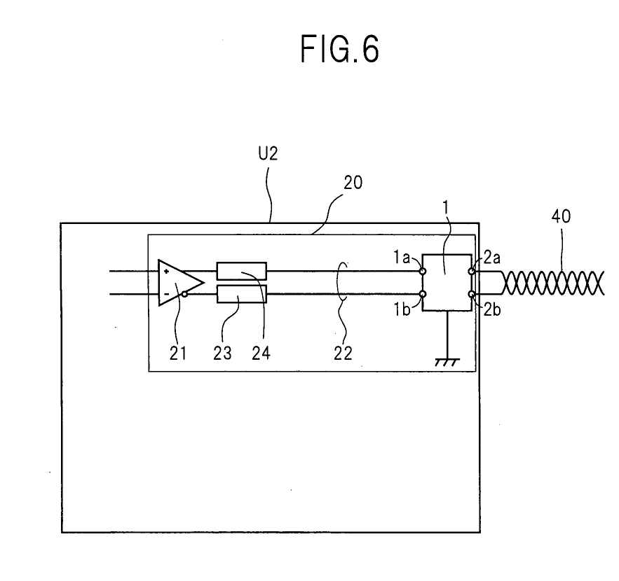

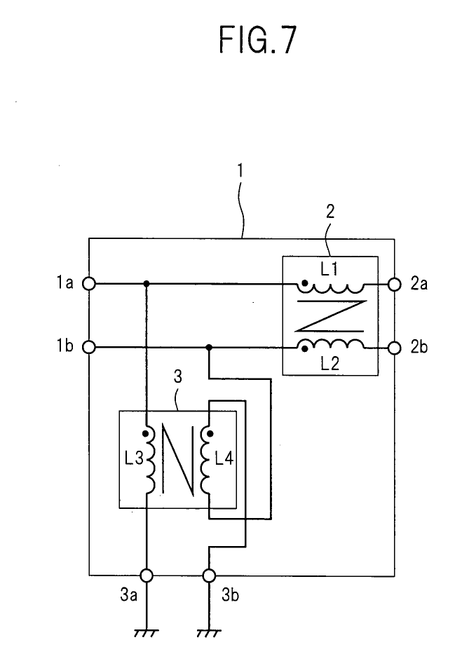

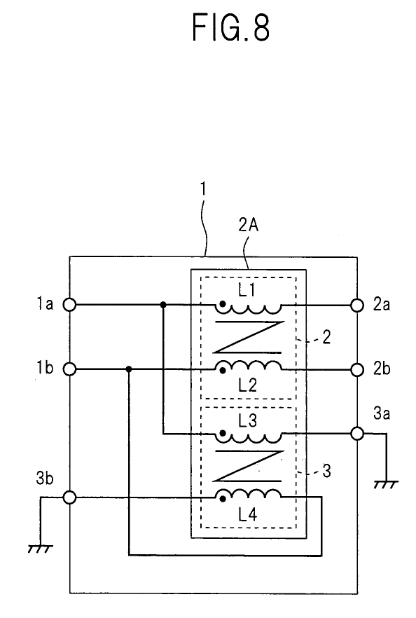

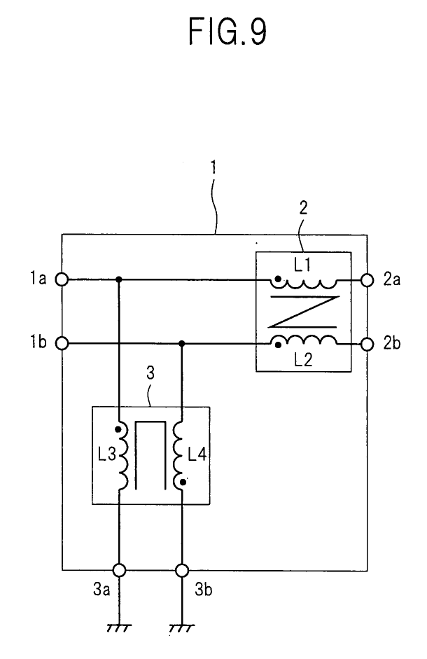

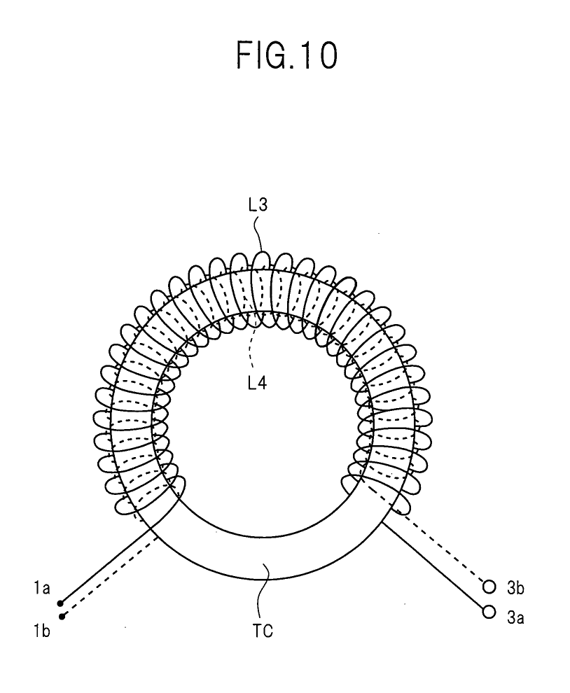

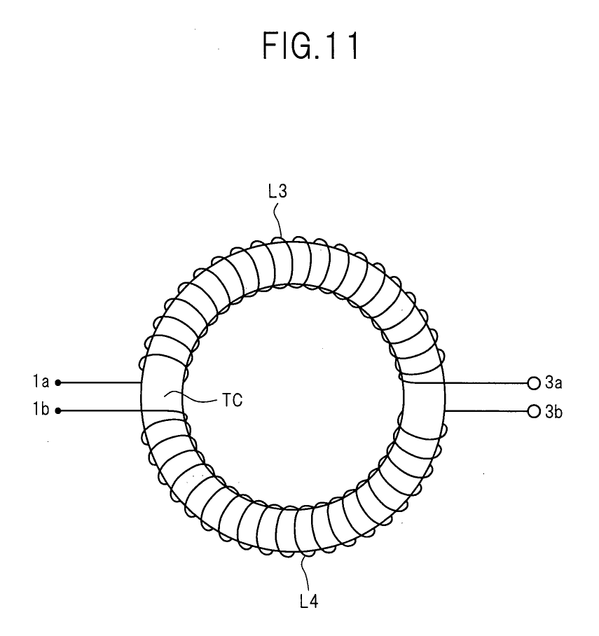

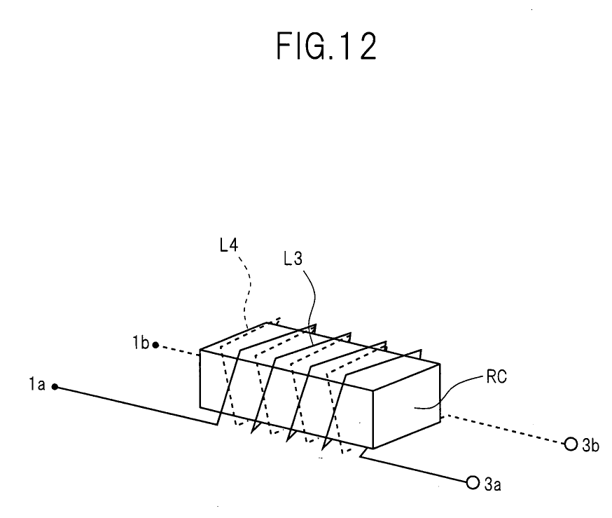

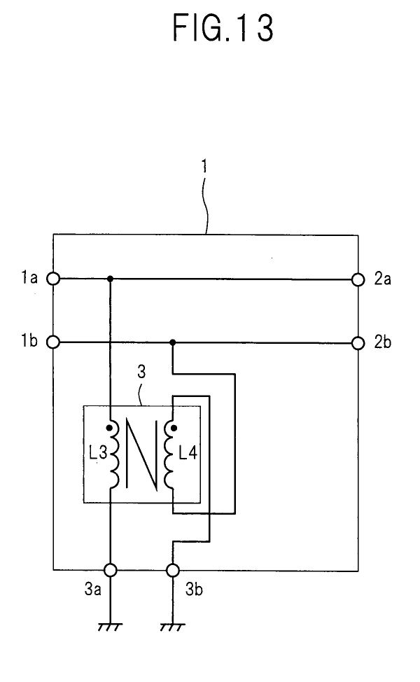

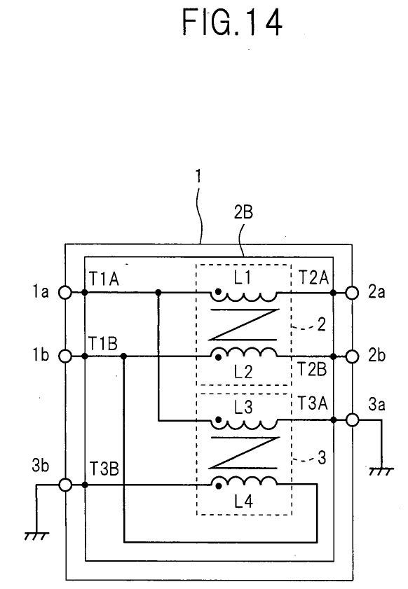

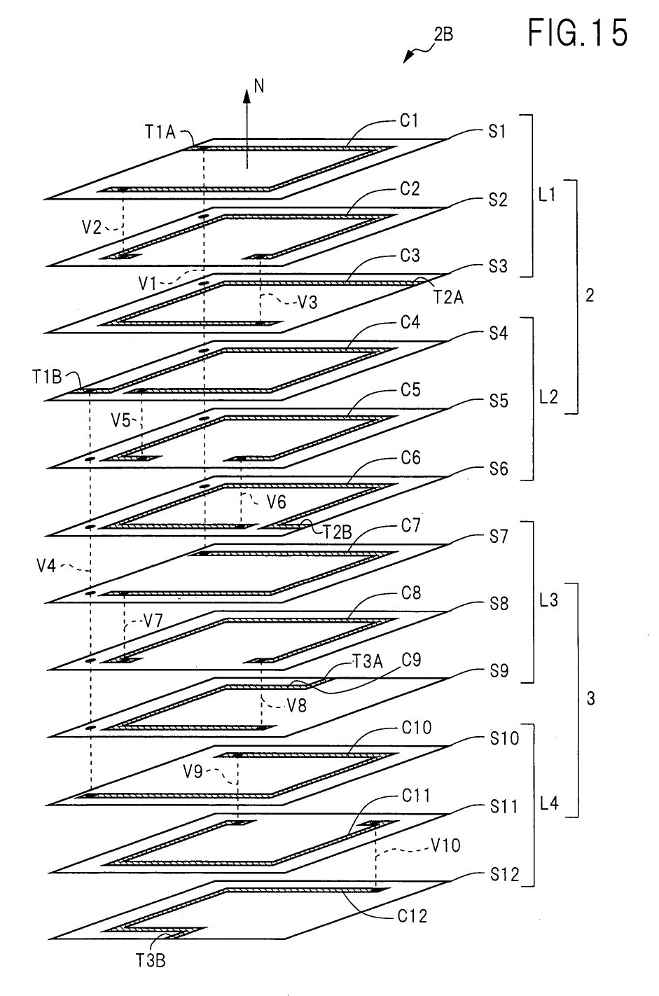

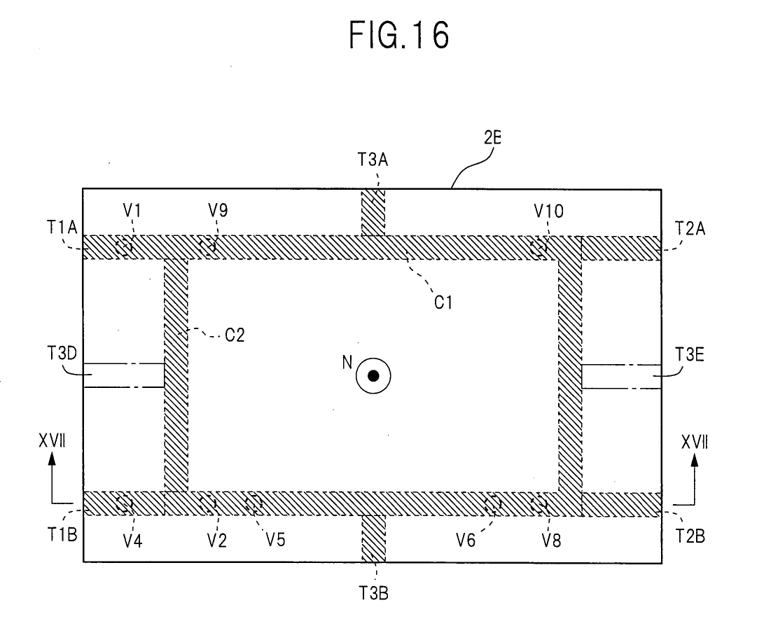

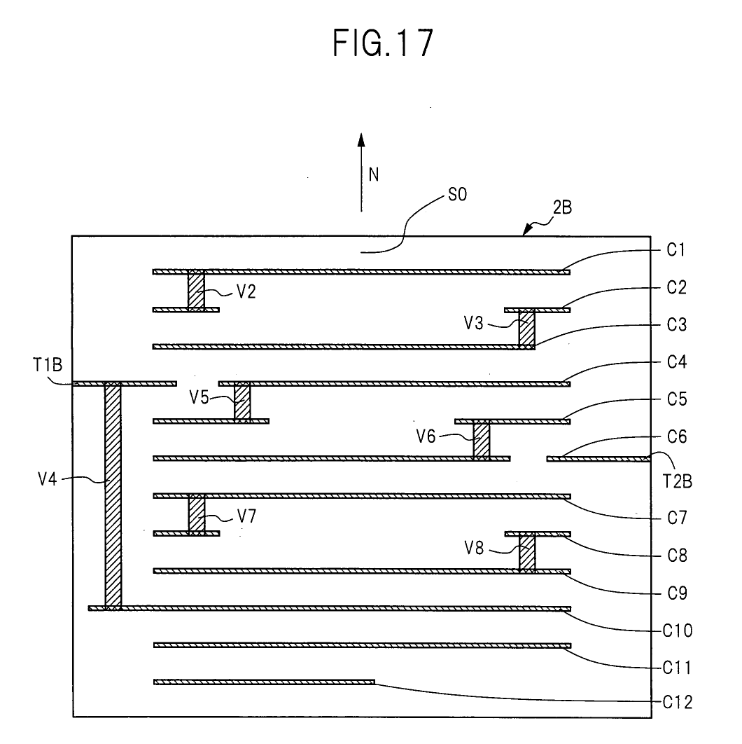

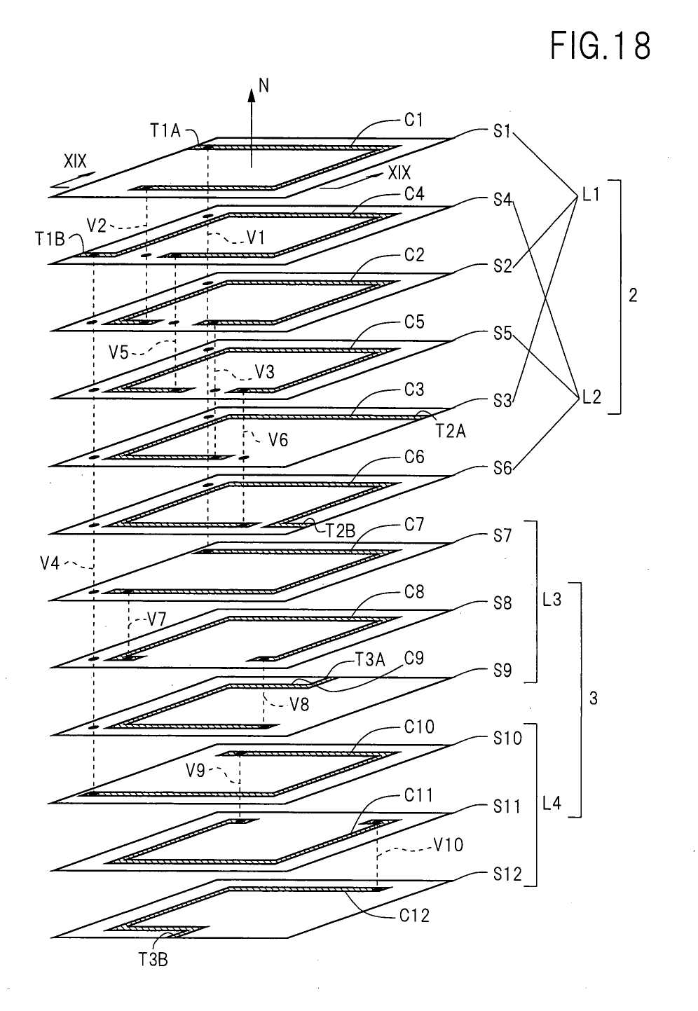

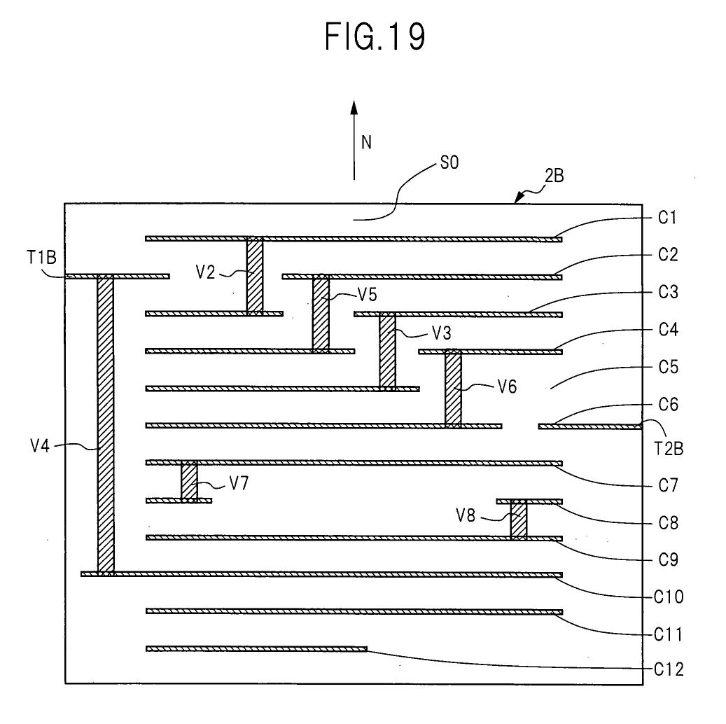

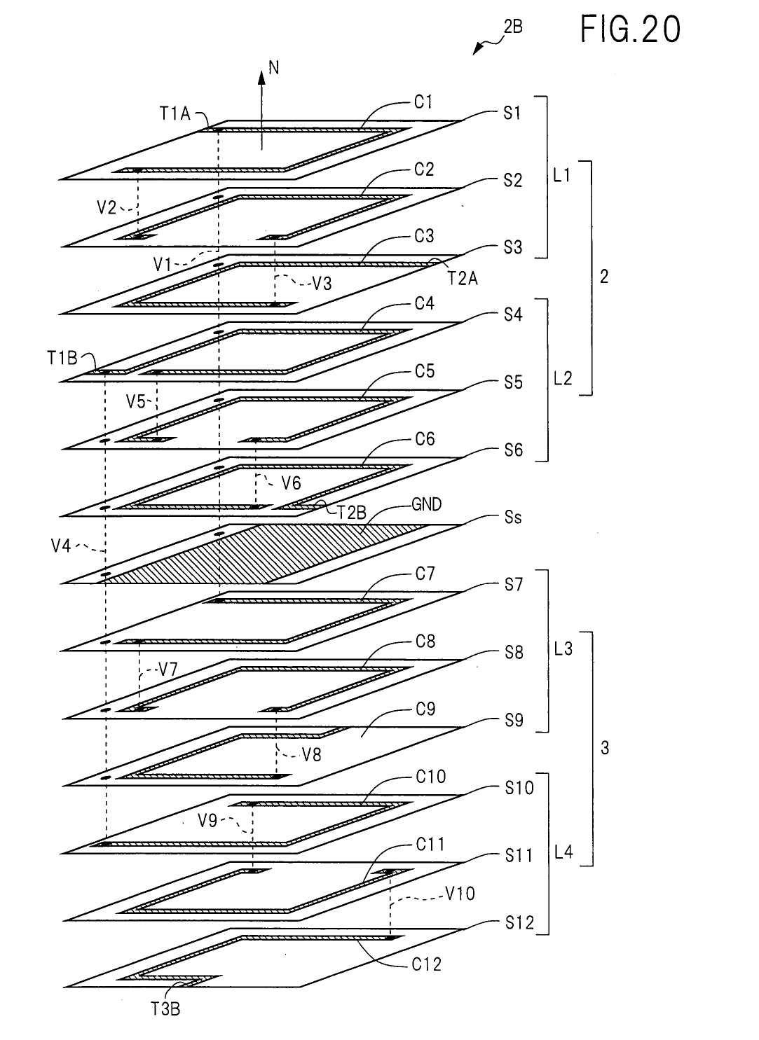

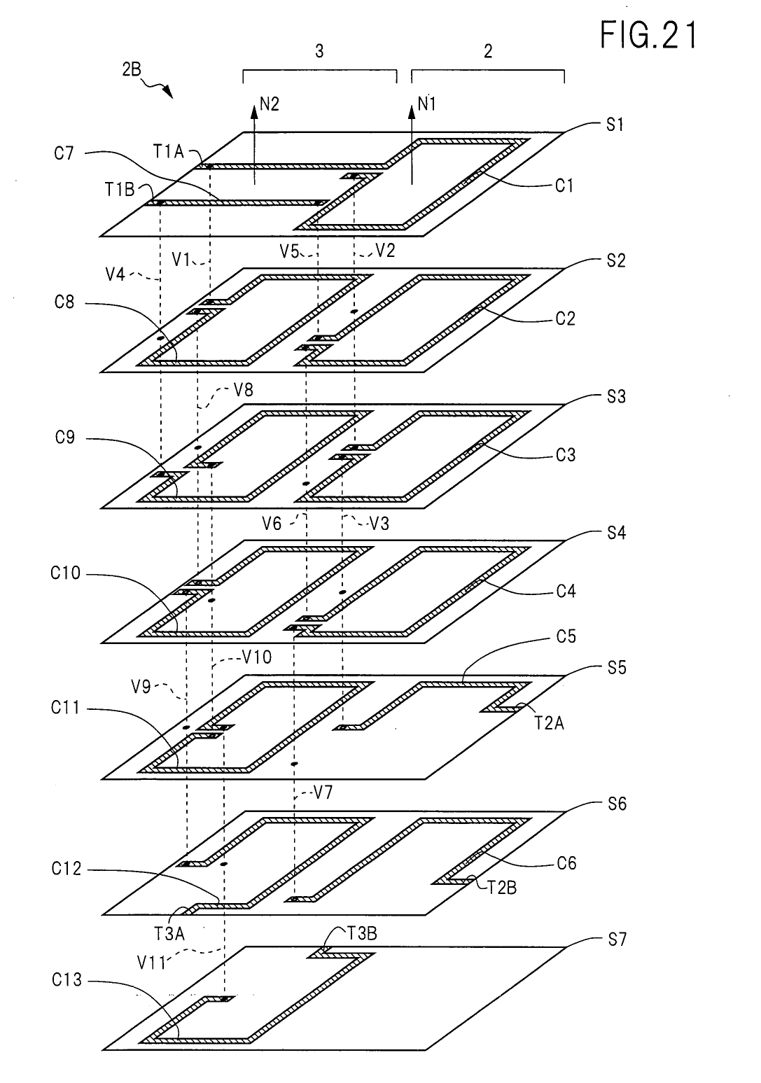

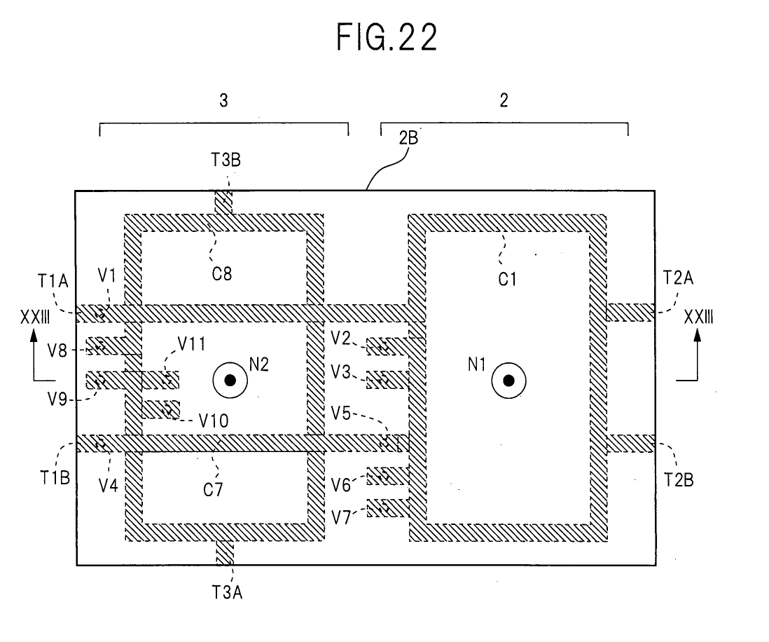

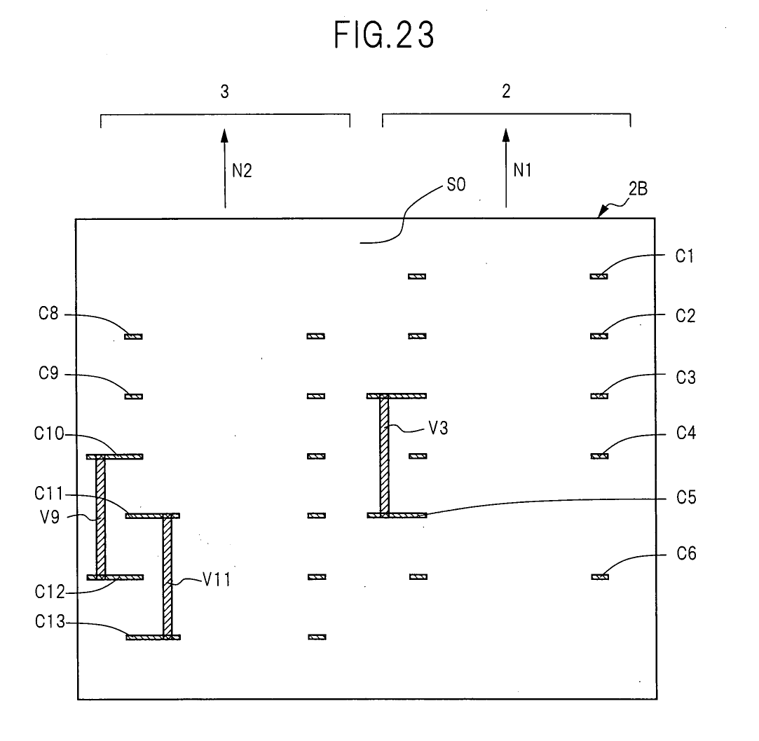

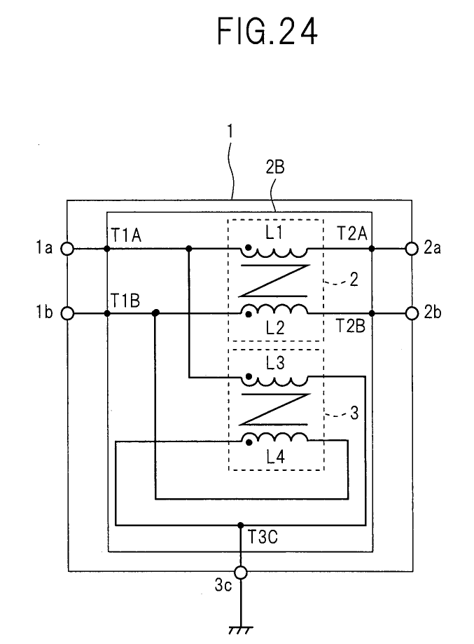

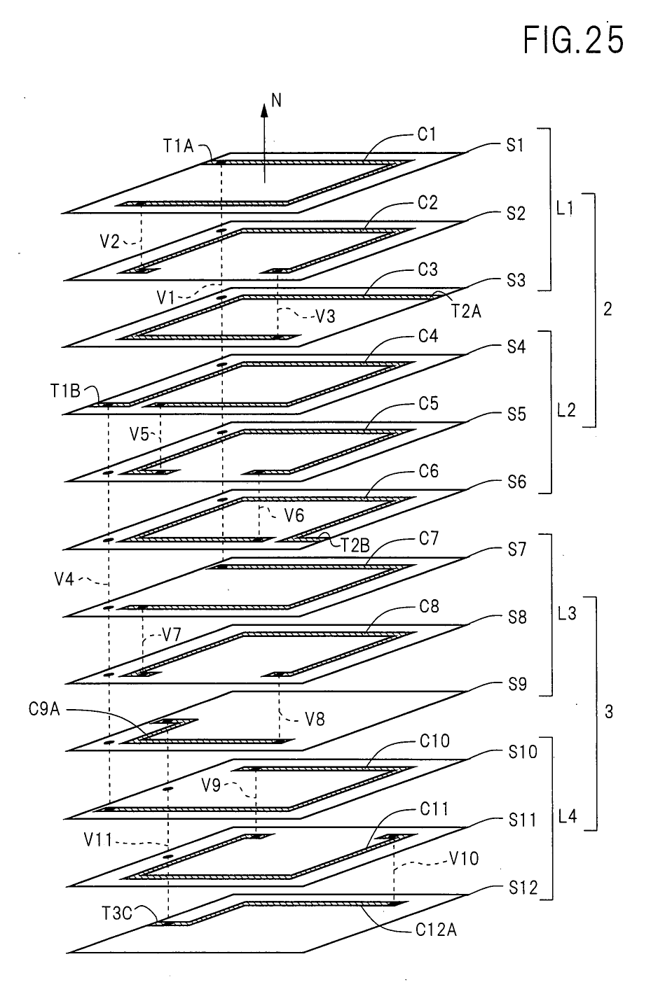

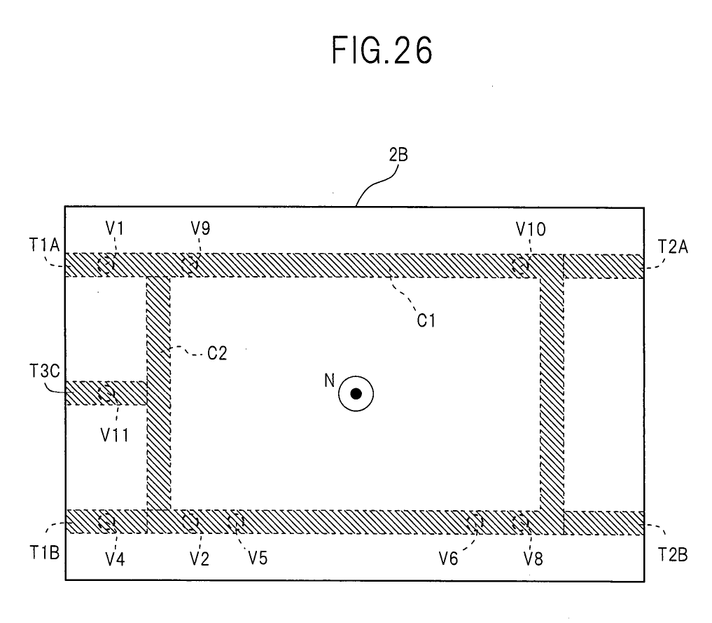

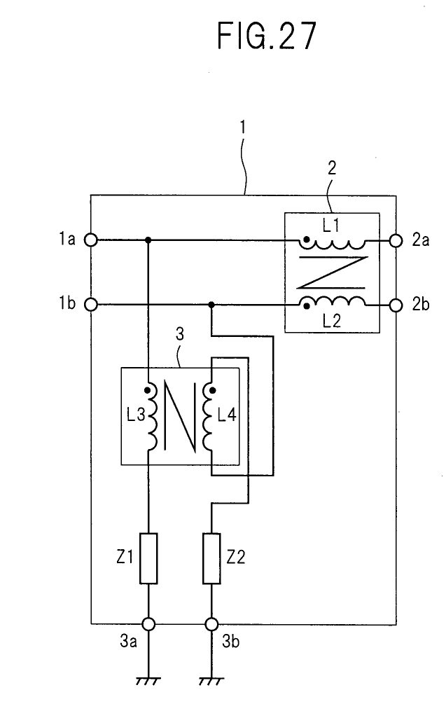

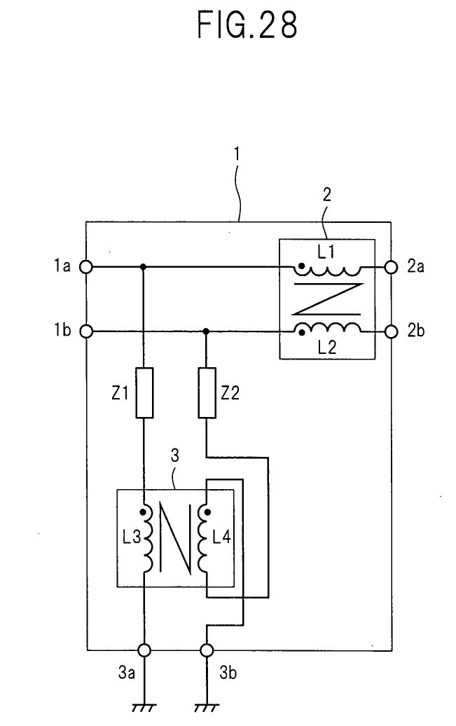

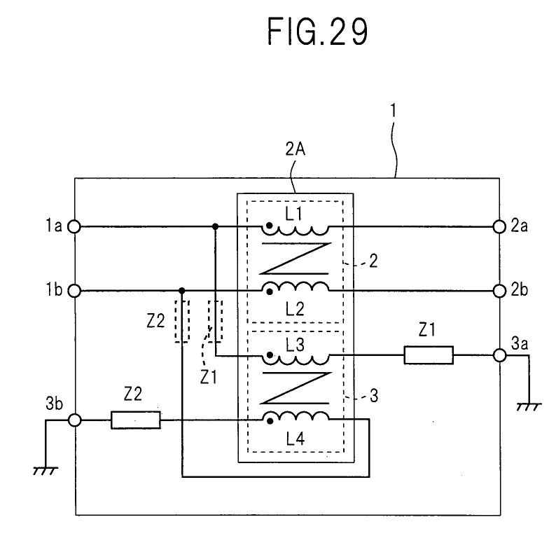

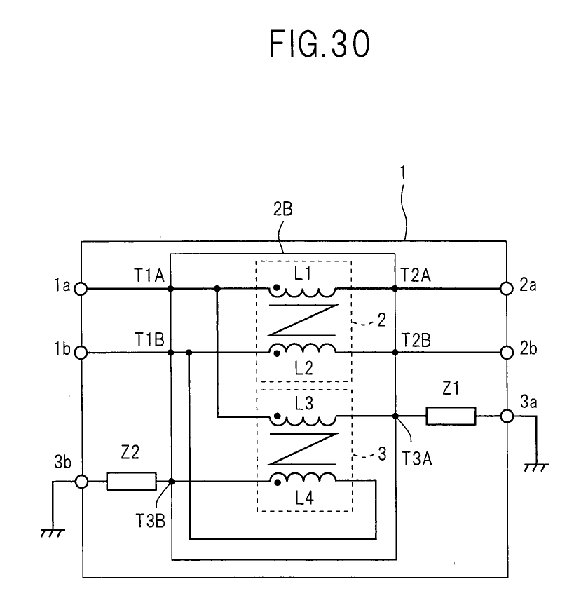

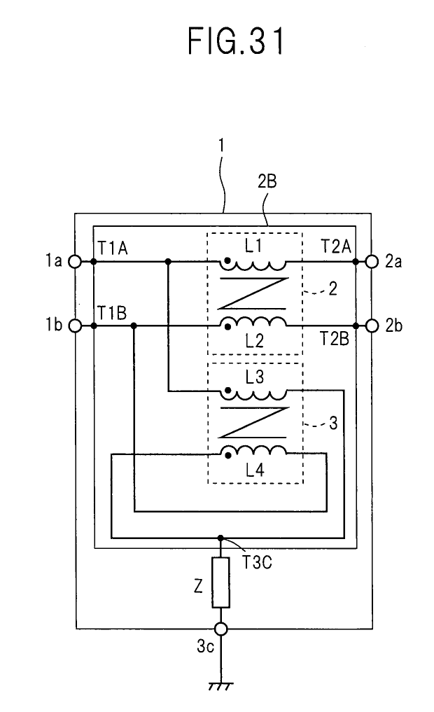

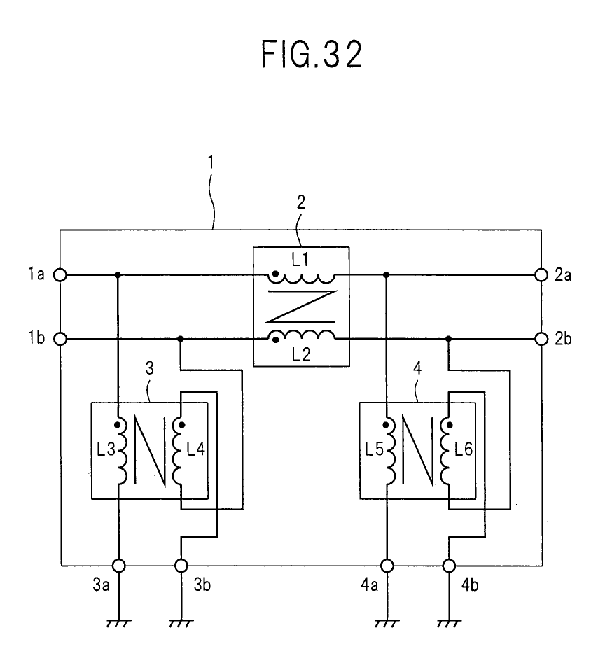

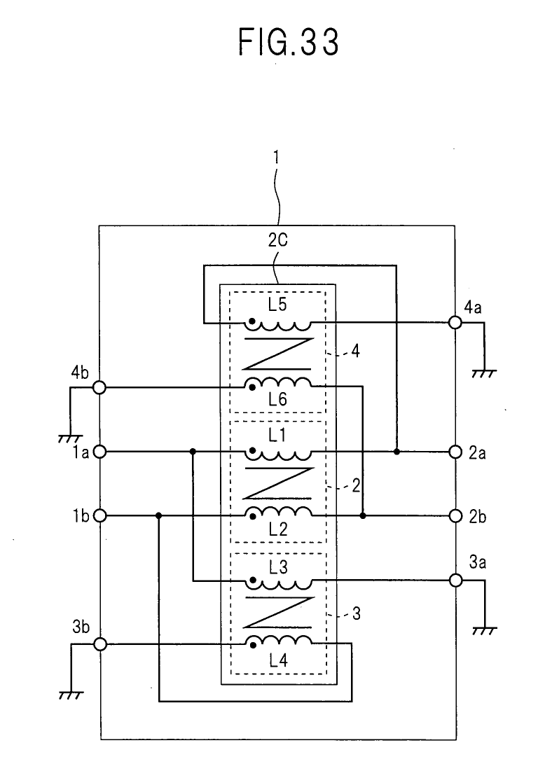

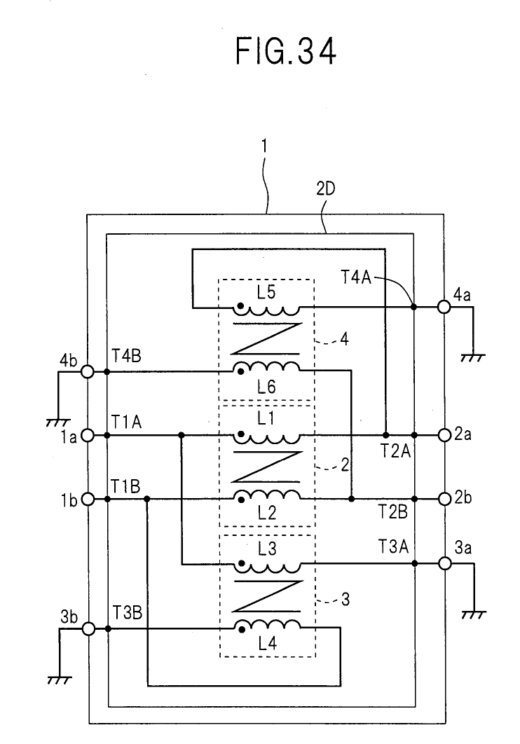

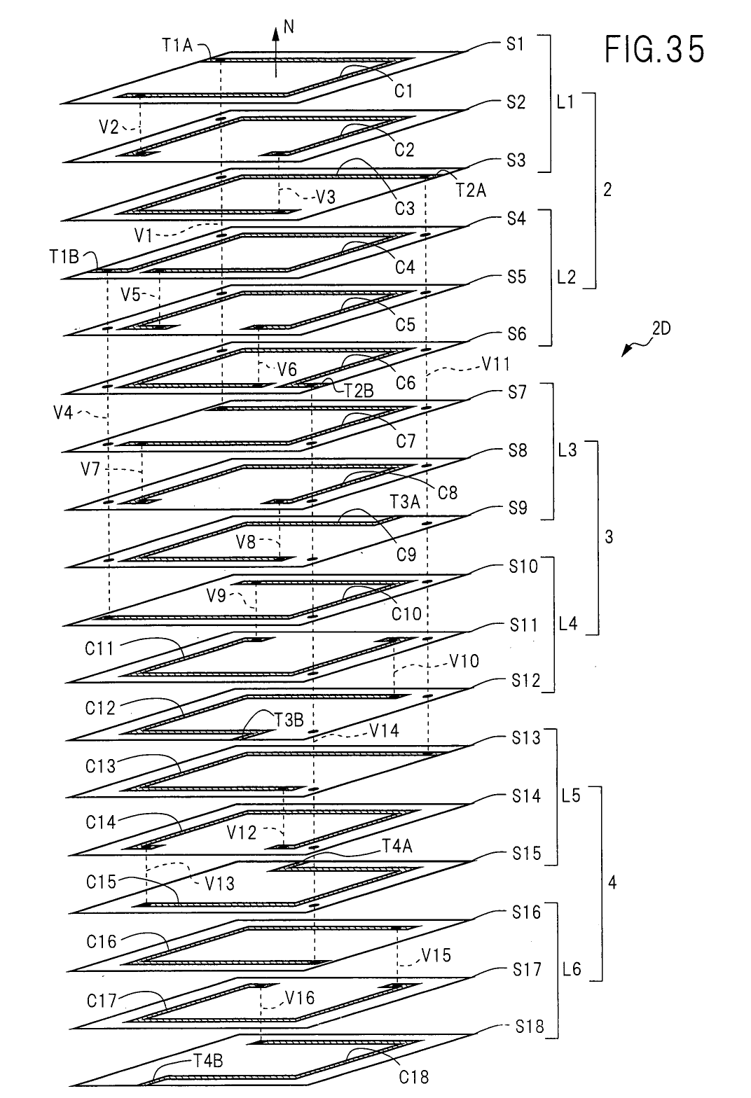

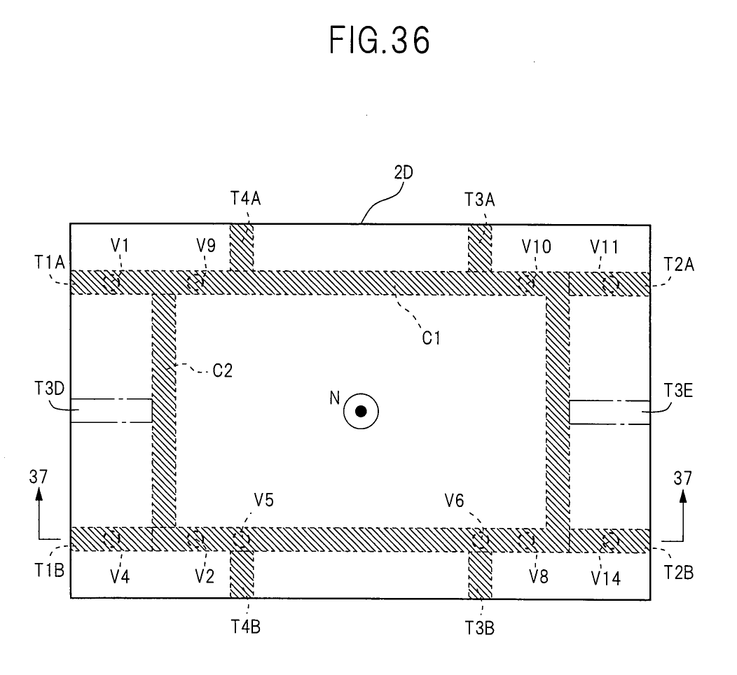

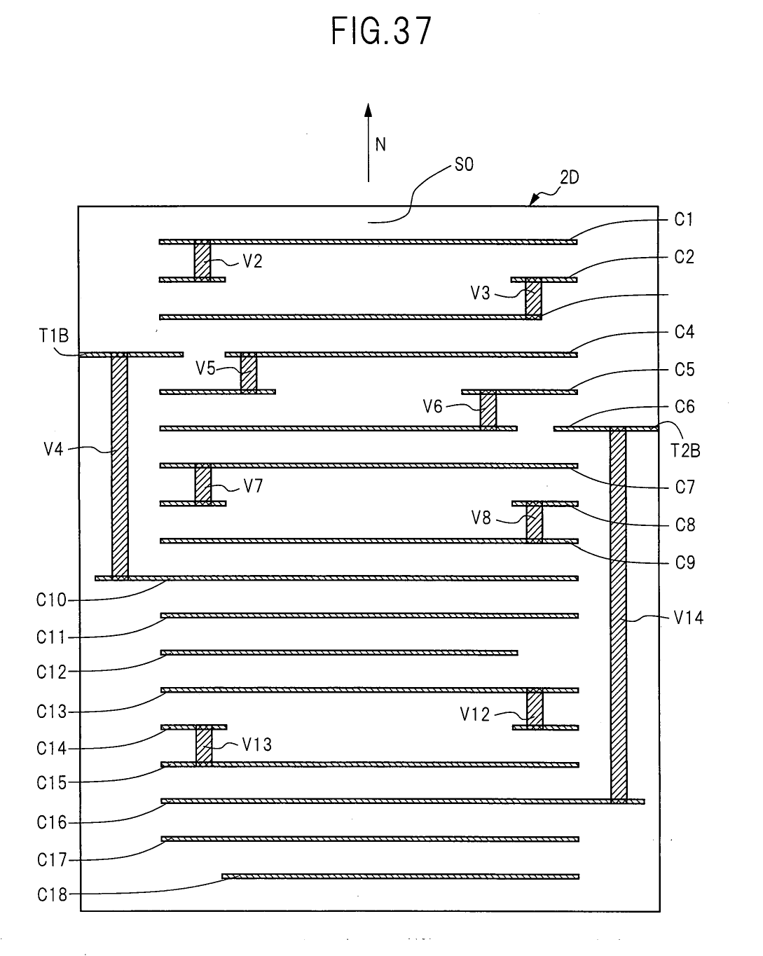

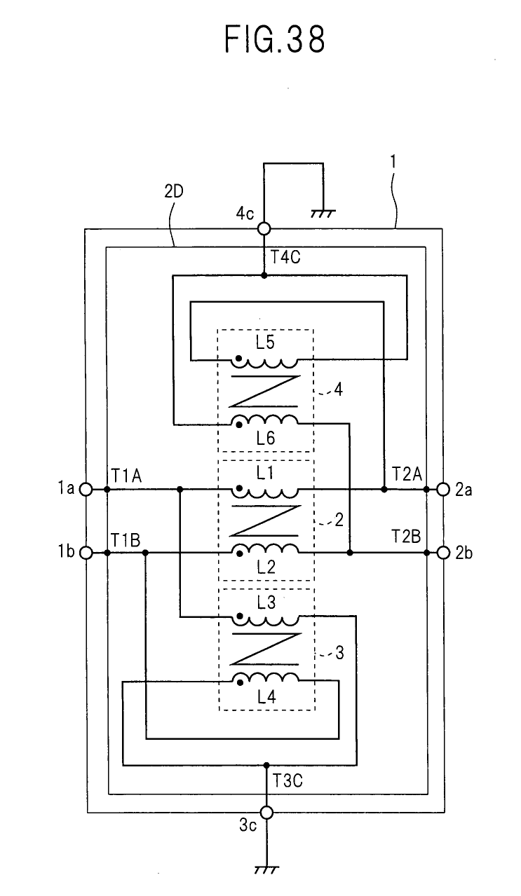

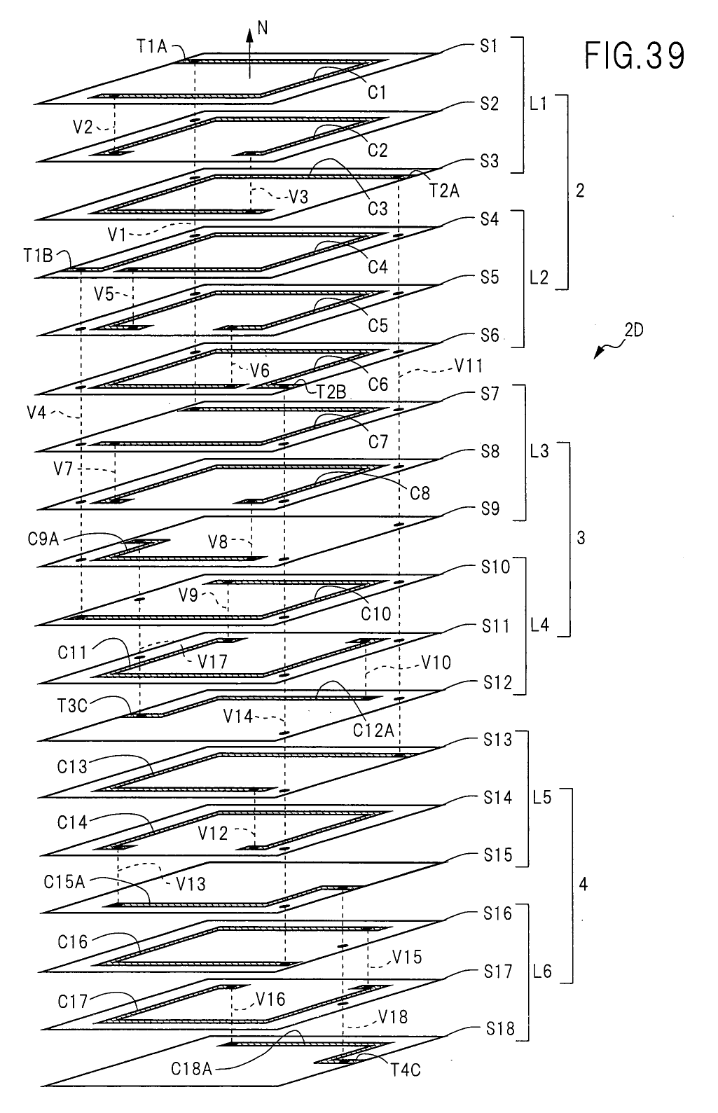

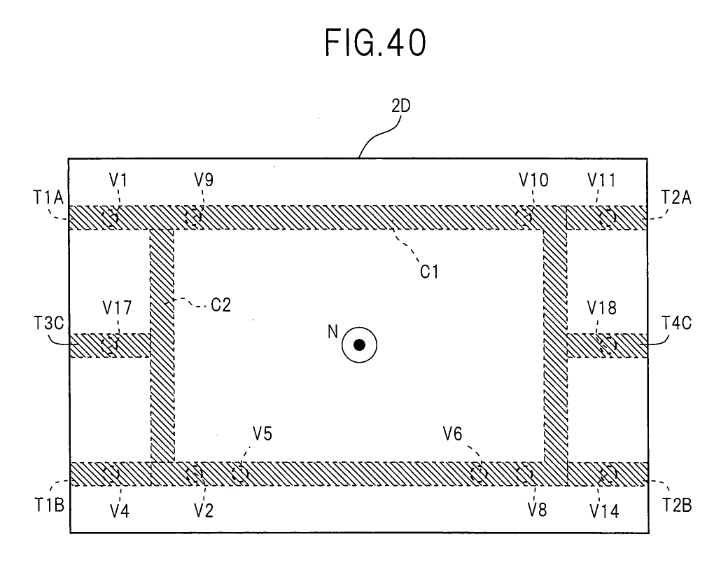

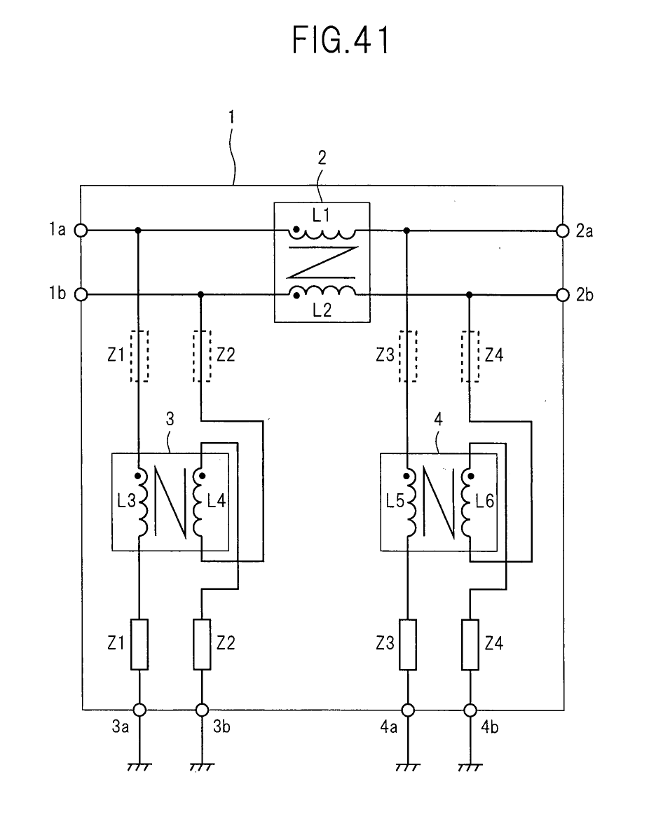

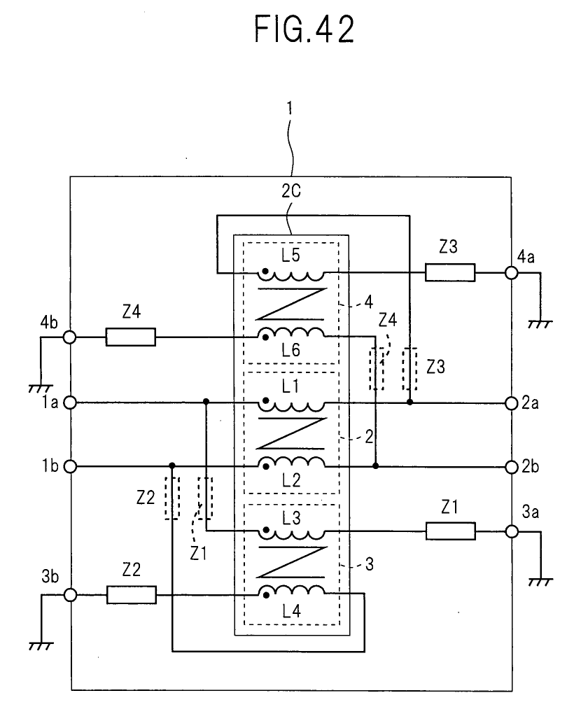

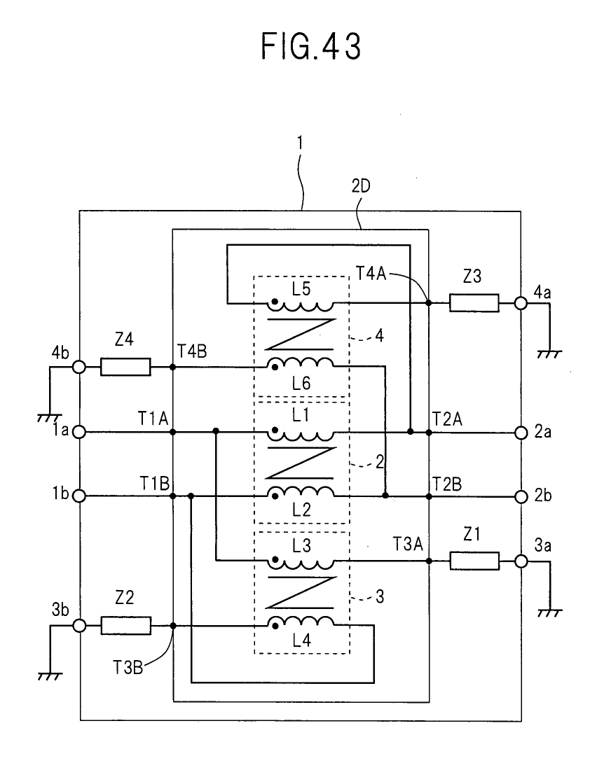

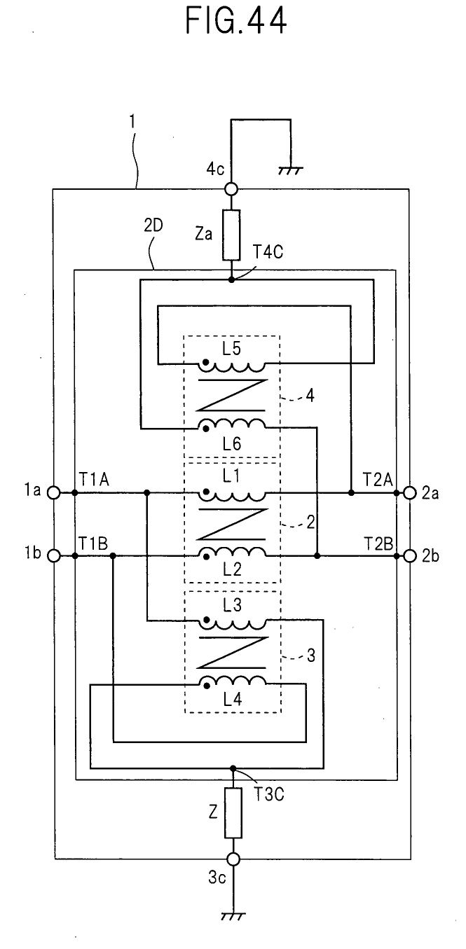

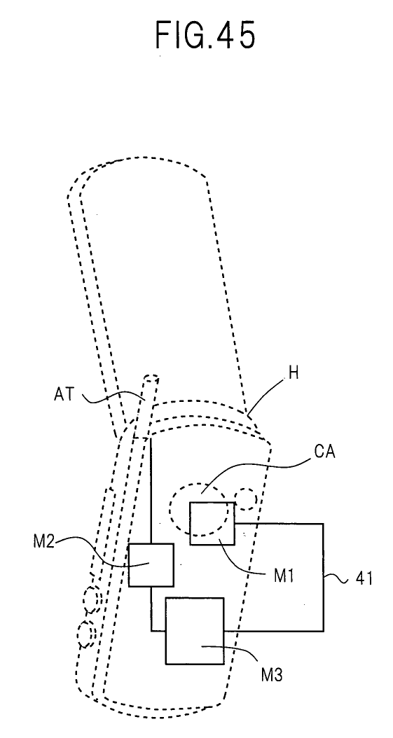

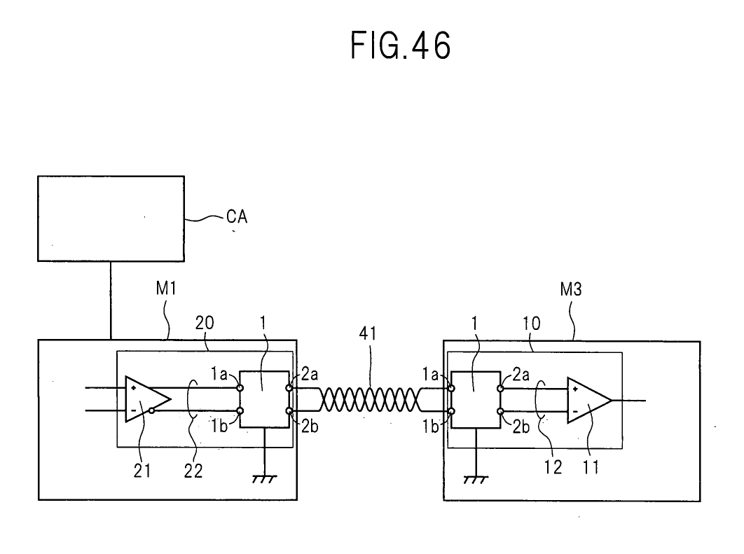

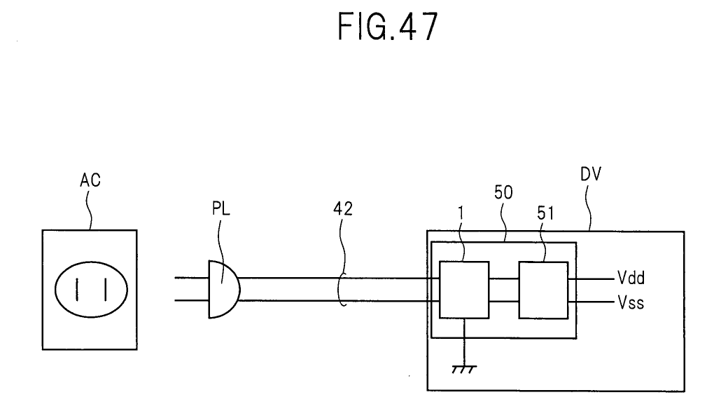

### BRIEF DESCRIPTION OF THE DRAWINGS

[FIG. 1] A block diagram which shows an in-car LAN according to Embodiment 1 of the present invention

[FIG. 2] A block diagram which shows the connection form of the in-car LAN shown in FIG. 1

[FIG. 3] A block diagram which shows another connection form of the in-car LAN shown in FIG. 1

[FIG. 4] A block diagram which shows a variation of the differential receiving device shown in FIGS. 2 and 3

[FIG. 5] A block diagram which shows another variation of the differential receiving device shown in FIGS. 2 and 3

[FIG. 6] A block diagram which shows a variation of the differential transmitting device shown in FIGS. 2 and 3

[FIG. 7] A diagram which shows an equivalent circuit of the filter circuit according to Embodiment 1 of the present invention

[FIG. 8] A diagram which shows an equivalent circuit of the filter circuit according to Embodiment 1 of the present invention that includes a common mode choke and a normal mode choke incorporated in a single package

[FIG. 9] A diagram which shows another equivalent circuit of the filter circuit according to Embodiment 1 of the present invention

[FIG. 10] A diagram which shows a type of the core of the normal mode choke shown in FIG. 9

[FIG. 11] A diagram which shows another type of the core of the normal mode choke shown in FIG. 9

[FIG. 12] A diagram which shows still another type of the core of the normal mode choke shown in FIG. 9

[FIG. 13] A diagram which shows still another equivalent circuit of the filter circuit according to Embodiment 1 of the present invention

[FIG. 14] A diagram which shows an equivalent circuit of the filter circuit according to Embodiment 2 of the present invention

[FIG. 15] An exploded perspective view which shows the common mode choke and the normal mode choke shown in FIG. 14

[FIG. 16] A plan view which shows the common mode choke and the normal mode choke shown in FIG. 15

[FIG. 17] A diagram which shows a cross section taken along the line XVII-XVII shown in FIG. 16

[FIG. 18] An exploded perspective view which shows another common mode choke and another normal mode choke included in the filter circuit according to Embodiment 2 of the present invention

[FIG. 19] A diagram which shows a cross section taken along the line XIX-XIX shown in FIG. 18

[FIG. 20] An exploded perspective view which shows a magnetic separation layer sandwiched between the common mode choke and the normal mode choke included in the filter circuit according to Embodiment 2 of the present invention

[FIG. 21] An exploded perspective view which shows still another common mode choke and still another normal mode choke included in the filter circuit according to Embodiment 2 of the present invention

[FIG. 22] A plan view of the common mode choke and the normal mode choke shown in FIG. 21

[FIG. 23] A diagram which shows a cross section taken along the line XXIII-XXIII shown in FIG. 22

[FIG. 24] A diagram which shows another equivalent circuit of the filter circuit according to Embodiment 2 of the present invention

[FIG. 25] An exploded perspective view which shows the common mode choke and the normal mode choke included in the filter circuit shown in FIG. 24

[FIG. 26] A plan view of the common mode choke and the normal mode choke shown in FIG. 25

[FIG. 27] A diagram which shows an equivalent circuit of the filter circuit according to Embodiment 3 of the present invention

[FIG. 28] A diagram which shows another equivalent circuit of the filter circuit according to Embodiment 3 of the present invention

[FIG. 29] A diagram which shows an equivalent circuit of the filter circuit according to Embodiment 3 of the present invention that includes a common mode choke and a normal mode choke incorporated in a single package

[FIG. 30] A diagram which shows an equivalent circuit of the filter circuit according to Embodiment 3 of the present invention that includes a common mode choke and a normal mode choke as a laminated (or thin-film) inductor

[FIG. 31] A diagram which shows an equivalent circuit of the filter circuit according to Embodiment 3 of the present invention in which the third and fourth output terminals are integrated into the same output terminal

[FIG. 32] A diagram which shows an equivalent circuit of the filter circuit according to Embodiment 4 of the present invention

[FIG. 33] A diagram which shows an equivalent circuit of the filter circuit according to Embodiment 4 of the present invention that includes a common mode choke and two normal mode chokes incorporated in a single package

[FIG. 34] A diagram which shows an equivalent circuit of the filter circuit according to Embodiment 5 of the present invention

[FIG. 35] An exploded perspective view which shows the common mode choke and the two normal mode chokes included in the filter circuit shown in FIG. 34

[FIG. 36] A plan view which shows the common mode choke and the two normal mode chokes shown in FIG. 35

[FIG. 37] A diagram which shows a cross section taken along the line 37-37 shown in FIG. 36

[FIG. 38] A diagram which shows another equivalent circuit of the filter circuit according to Embodiment 5 of the present invention

[FIG. 39] An exploded perspective view which shows the common mode choke and the two normal mode chokes included in the filter circuit shown in FIG. 38

[FIG. 40] A plan view which shows the common mode choke and the two normal mode chokes shown in FIG. 39

[FIG. 41] A diagram which shows an equivalent circuit of the filter circuit according to Embodiment 6 of the present invention

[FIG. 42] A diagram which shows an equivalent circuit of the filter circuit according to Embodiment 6 of the present invention that includes a common mode choke and two normal mode chokes incorporated in a single package

[FIG. 43] A diagram which shows an equivalent circuit of the filter circuit according to Embodiment 6 of the present invention that includes a common mode choke and two normal mode chokes as a laminated (or thin-film) inductor

[FIG. 44] A diagram which shows an equivalent circuit of the filter circuit according to Embodiment 6 of the present invention in which the third and fourth output terminals are integrated into a single output terminal, and the fifth and sixth output terminals are integrated into another single output terminal

[FIG. 45] A block diagram which shows a portable information apparatus according to Embodiment 7 of the present invention

[FIG. 46] A block diagram which shows a differential transmission system according to Embodiment 7 of the present invention that is installed in the portable information apparatus shown in FIG. 45

[FIG. 47] A block diagram which shows a power supply according to Embodiment 8 of the present invention

[FIG. 48] An equivalent circuit diagram which shows a conventional filter circuit

[FIG. 49] An equivalent circuit diagram which shows another conventional filter circuit

### EXPLANATION OF REFERENCE SYMBOLS

1 Filter circuit
1a First input terminal
1b Second input terminal
2 Common mode choke
L1 First inductor
L2 Second inductor
2a First output terminal
2b Second output terminal
3 Normal mode choke
L3 Third inductor
L4 Fourth inductor
3a Third output terminal
3b Fourth output terminal

### DETAILED DESCRIPTION OF THE PREFERRED EMBODIMENTS

The preferred embodiments of the present invention will be explained below with reference to the drawings.

### Embodiment 1

A differential transmission system according to Embodiment 1 of the present invention is preferably installed in an in-car LAN such as CAN. (cf. FIG. 1). Various ECUs connected to the in-car LAN include, for example; ECUs E1 to control a driving system (powertrain) such as an engine, a transmission, and a brake; ECUs E2 to control safety devices (safety system) such as an ABS and airbags; and ECUs E3 to control attachments (body control system) such as headlights, an air conditioner, and side-view mirrors. In-car-LAN-connected devices further include; various sensors such as an in-car camera, a laser for measurement of a distance between cars, and an acceleration sensor; information electronic appliances (ITS) E4 such as a car navigation system and an ETC; and AV apparatuses such as a DVD player and a stereo system component. Such ECUs and in-car electronic appliances (hereinafter, abbreviated as ECUs, etc.) are preferably connected in bus configuration, or alternatively, may be connected in star configuration. Various ECUs, etc. communicate and operate in conjunction with each other through the in-car LAN, and thereby, realize various advanced functions.

Cables 40 connect between the ECUs, etc. in the in-car LAN. Each of the cables 40 is long in general (for example, 2 m or more). On the other hand, electromagnetic waves are radiated in a car from various components such as the engine E and the motors that rotate door mirrors DM. Furthermore, the car runs through various environments, and accordingly, various electromagnetic waves get into the inside of the car from the outside. Those electromagnetic waves generate noises in the cables 40. In addition to the noises, noises directly sent from the ECUs, etc., to the cables 40 are radiated as electromagnetic waves into the surroundings of the cables 40, and then, produce noises in other cables 40 and an antenna AT. Thus, the degree of EMI radiation and the accompanying noises are both high in the in-car LAN. In order to prevent such noises from adversely affect ECUs, etc., that is, to reduce EMI, communication in the in-car LAN is performed by a differential transmission scheme.

The ECUs, etc. U1, U2, U3, . . . , include a differential receiving device 10, a differential transmitting device 20, and a differential transmitting and receiving device 30, respectively, as a communication port (cf. FIGS. 2, 3). The communication ports are connected with each other through the cables 40, and then, constitute a differential transmission system. Each of the cables 40 includes two differential lines. Each of opposite-phase signals (differential signals) propagates through one of the differential lines. Shielded twist pair cables are preferably used as the cables 40, or alternatively, unshielded twist pair cables, flat cables, or flexible cables may be used. The cables 40 preferably connect the communication ports in a one-to-one manner (cf. FIG. 2). In that case, the ECUs, etc., U1, U2, U3, . . . , which each repeat a received signal to the next ECUs, etc., logically constitute a bus-connected LAN. Alternatively, cables may be physically divided into a bus 40B and branch lines 40A (cf. FIG. 3).

The differential receiving device 10 is a receive-only device, and installed in, for example, a display U1 (cf. FIGS. 2, 3). The differential receiving device 10 includes a filter circuit 1 according to the present invention, a differential receiver 11, and a differential line 12. Two input terminals 1a and 1b of the filter circuit 1 are connected to the differential line included in the cable 40. Here, a DC blocking capacitor, an ESD protection diode, and the like may be further connected between the cable 40 and the filter circuit 1. The filter circuit 1 receives differential signals from other ECUs, etc., through the cable 40, and then eliminates common-mode noises from the differential signals. In particular, the filter circuit 1 allows substantially all normal-mode components of the differential signals to pass, while it absorbs substantially all common-mode noises without reflecting them (details thereof will be described below). Two output terminals 2a and 2b of the filter circuit 1 are connected to the differential line 12. Here, a low pass filter, for example, may be connected between the filter circuit 1 and the differential line 12. Input ports of the differential receiver 11 receive differential signals sent from the filter circuit 1 through the differential line 12. The differential receiver 11 amplifies the differences of the received differential signals. The display U1, for example, decodes the output signals of the differential receiver 11 into image data, and, based on it, reproduces images on the screen.

Preferably, a terminator element 13, 14, or 15 is further connected to the input ports of the differential receiver 11 in the differential receiving device 10 (cf. FIGS. 4, 5). The terminator elements 13, 14, and 15 are preferably resistance elements, and integrated into a single LSI, together with the differential receiver 11. In FIG. 4, each input terminal of the differential receiver 11 is connected to a fixed potential terminal (preferably, a ground terminal) through the terminator element 13 or 14. In FIG. 5, the input terminals of the differential receiver 11 are connected across the terminator element 15. The impedance of the filter circuit 1 is sufficiently low for differential signals. Accordingly, the differential impedance of the differential line 12 and the impedances of the terminator elements 13, 14, and 15 are each adjusted to match the differential impedances of the cable 40. For example, when the differential impedance of the cable 40 is 100Ω, the differential impedance of the differential line 12 is set at about 100Ω. Furthermore, each impedance of the terminator elements 13 and 14 is set at about 50Ω in FIG. 4, and the impedance of the terminator element 15 is set at about 100Ω in FIG. 5. As a result, neither substantial distortion nor attenuation occurs in the differential signals received by the differential receiver 11. In addition, the layout of the differential line 12 circumvents constraints of impedance matching, and therefore, the differential receiving device 10 has a high degree of flexibility in circuit design.

The differential transmitting device 20 is a transmit-only device, and installed in, for example, a control circuit U2 of the display U1 (cf. FIGS. 2, 3). The differential transmitting device 20 includes a differential driver 21, a filter circuit 1 according to the present invention, and a differential line 22. Differential signals are generated in the control circuit U2, for example, based on image data. The differential driver 21 amplifies the differential signals. The amplified differential signals are sent from the output ports of the differential driver 21 to the differential line 22. Two input terminals 1a and 1b of the filter circuit 1 are connected to the differential line 22. Here, for example, a low pass filter may be connected between the differential line 22 and the filter circuit 1. The filter circuit 1 receives the differential signals through the differential line 22, and then eliminates common-mode noises from the differential signals. In particular, the filter circuit 1 allows substantially all normal-mode components of the differential signals to pass, while it absorbs substantially all common-mode noises without reflecting them (the details are described below). Two output terminals 2a and 2b of the filter circuit 1 are connected to the differential line included in the cables 40. Here, a DC blocking capacitor, an ESD protection diode, and the like may be further connected between the filter circuit 1 and the cable 40. The filter circuit 1 sends differential signals to other ECUs, etc., through the cables 40.

More preferably, the output ports of the differential driver 21 are connected to the differential line 22 through the terminator elements 23 and 24 (cf. FIG. 6). The terminator elements 23 and 24 are preferably resistance elements, and more preferably, integrated into a single LSI, together with the differential driver 21. Alternatively, they may be mounted as discrete elements separated from the differential driver 21. Since the differential impedance of the filter circuit 1 is sufficiently low, the differential impedance of the differential line 22 is adjusted to match the differential impedance of the cable 40, and the composition of the on resistance of the differential driver 21 and the impedance of the terminator element 23 or 24 is also adjusted to match the differential impedance of the cable 40. For example, when the differential impedance of the cable 40 is 100Ω, the differential impedance of the differential line 22 is set at about 100Ω, and the composition of the on resistance of the differential driver 21 and the impedance of the terminator element 23 or 24 is set at about 50Ω. As a result, neither substantial distortion nor attenuation occurs in the differential signals sent to the cable 40. In addition, the layout of the differential line 22 circumvents constraints of impedance matching, and therefore, the differential transmitting device 20 has a high degree of flexibility in circuit design.

The differential transmitting and receiving device 30 is a device into which the differential receiving device 10 and the differential transmitting device 20 are unified, and is installed in an ECU, etc., U3, which performs both transmission and reception (cf. FIGS. 2, 3). The differential transmitting and receiving device 30 includes a differential receiver 31, a differential driver 32, a filter circuit 1 according to the present invention, and a differential line 33.

Two input terminals 1a and 1b of the filter circuit 1 are connected to the differential line included in the cable 40. Here, a DC blocking capacitor, an ESD protection diode, and the like may be further connected between the cable 40 and the filter circuit 1. The filter circuit 1 receives differential signals from other ECUs, etc., through the cable 40, and then eliminates common-mode noises from the differential signals. In particular, the filter circuit 1 allows substantially all normal-mode components of the differential signals to pass, while it absorbs substantially all common-mode noises without reflecting them (details thereof will be described below). Two output terminals 2a and 2b of the filter circuit 1 are connected to the differential line 33. Here, a low pass filter, for example, may be connected between the filter circuit 1 and the differential line 33. Input ports of the differential receiver 31 receive differential signals sent from the filter circuit 1 through the differential line 33. The differential receiver 31 amplifies the differences of the received differential signals. The ECU, etc., U3 decodes the output signals of the differential receiver 31 into communication data.

Differential signals are generated in the ECU, etc., U3, based on data to be sent to other ECUs, etc. The differential driver 32 amplifies the differential signals. The amplified differential signals are sent from the output ports of the differential driver 32 to the differential line 33. The filter circuit 1 receives the differential signals through the differential line 33, the first output terminal 2a, and the second output terminal 2b, and then eliminates common-mode noises from the differential signals. In particular, the filter circuit 1 allows substantially all normal-mode components of the differential signals to penetrate completely. The filter circuit 1 further sends differential signals to the cable 40 through the first input terminal 1a and the second input terminal 1b. As described above, the two input terminals 1a, 1b, and the two output terminals 2a, 2b of the filter circuit 1 are all used as input and output terminals in the differential transmitting and receiving device 30.

Preferably, a terminator element 13, 14, or 15 is connected to the input ports of the differential receiver 31 in the differential transmitting and receiving device 30 (cf. FIGS. 4, 5), in a similar manner to that of the differential receiving device 10. Thereby, neither substantial distortion nor attenuation occurs in the differential signals received by the differential receiver 31. More preferably, the output ports of the differential driver 32 are connected to the differential line 33 through the terminator elements 23 and 24, respectively (cf. FIG. 6), in a similar manner to that of the differential transmitting device 20. Thereby, neither substantial distortion nor attenuation occurs in the differential signals sent to the cable 40. In addition, the layout of the differential line 33 circumvents constraints of impedance matching, and therefore, the differential transmitting and receiving device 30 has a high degree of flexibility in circuit design.

The filter circuit 1 comprises two input terminals 1a, 1b, four output terminals 2a, 2b, 3a, 3b, a common mode choke 2, and an normal mode choke 3 (cf. FIG. 7). The two input terminals 1a and 1b are connected to the cable 40 in the differential receiving device 10 and the differential transmitting and receiving device 30, and connected to the output terminals of the differential driver 21 in the differential transmitting device 20, as shown in FIGS. 2 and 3. A first output terminal 2a and a second output terminal 2b are connected to the input terminals of the differential receiver 11 and 31 in the differential receiving device 10 and the differential transmitting and receiving device 30, and connected to the cable 40 in the differential transmitting device 20, as shown in FIGS. 2 and 3. A third output terminal 3a and a fourth output terminal 3b are connected to a fixed potential terminal (preferably, a ground terminal).

The common mode choke 2 includes two inductors L1 and L2. The first inductor L1 is connected between the first input terminal 1a and the first output terminal 2a. The second inductor L2 is connected between the second input terminal 1b and the second output terminal 2b. The two inductors L1 and L2 are magnetically coupled to each other, and in particular, they are connected between the input terminal and the output terminal in the same polarity. In other words, when a common mode current flows between the two input terminals 1a and 1b and the two output terminals 2a and 2b, magnetic fluxes which appear in the two inductors L1 and L2 enhance each other, and when a normal mode current flows between the two input terminals 1a and 1b and the two output terminals 2a and 2b, magnetic fluxes which appear in the two inductors L1 and L2 cancel each other out. Thereby, the impedance of the common mode choke 2 is extremely high for the common mode components of the signals received through the two input terminals 1a and 1b, and extremely low for the normal mode components of the signals. The common mode choke 2 includes a single core and two coils that are wound around the core, in Embodiment 1 of the present invention. Preferably, the two coils are wound around the core in the directions of windings of a bifilar or cancel coil.

The normal mode choke 3 includes two inductors L3 and L4. The third inductor L3 is connected between the first input terminal 1a and the third output terminal 3a. The fourth inductor L4 is connected between the second input terminal 1b and the fourth output terminal 3b. The two inductors L3 and L4 magnetically couple to each other, and in particular, they are connected between the input terminals and the output terminals in the opposite polarities. In other words, when a normal mode current flows between the two input terminals 1a and 1b and the two output terminals 3a and 3b, magnetic fluxes which appear in the two inductors L3 and L4 enhance each other, and when a common mode current flows between the two input terminals 1a and 1b and the two output terminals 3a and 3b, magnetic fluxes which appear in the two inductors L3 and L4 cancel each other out. Thereby, the impedance of the normal mode choke 3 is extremely high for the normal mode components of the signals received through the two input terminals 1a and 1b, and extremely low for the common mode components of the signals.

The normal mode choke 3 includes a single core and two coils that are wound around the core in Embodiment 1 of the present invention. Preferably, the two coils are wound around the core in the directions of windings of a bifilar or cancel coil. In other words, the normal mode choke 3 has the same configuration as the common mode choke 2. In that case, as shown in FIG. 7, the third inductor L3 and the fourth inductor L4 have opposite polarities in the connection to the respective input/output terminals. More preferably, a common mode choke array 2A that includes two common mode chokes is used as a combination of the common mode choke 2 and the normal mode choke 3 according to Embodiment 1 of the present invention (cf. FIG. 8). Thereby, the common mode choke 2 and the normal mode choke 3 are integrated into a single package, and this offers an advantage in miniaturization of the filter circuit 1.

In another normal mode choke 3, two coils may be wound around the core in the directions so that the magnetic fluxes caused by common mode currents cancel each other out (cf. FIG. 9). In other words, one of the two coils is wound in the reversed direction of windings of a bifilar or cancel coil (cf. FIGS. 10, 11, and 12). In FIG. 10, two coils L3 and L4 are wound around the toroidal core TC one over the other (the coil shown by a solid line corresponds to the third inductor L3, and the coil shown by a broken line corresponds to the fourth inductor L4). However, the two coils L3 and L4 are wound in the opposite directions around the toroidal core TC, in contrast to bifilar windings. In FIG. 11, each half turn of two coils L3 and L4 are separately wound around the toroidal core TC. However, the two coils L3 and L4 are wound around the toroidal core TC in the same manner, in contrast to bifilar windings. In FIG. 12, two coils L3 and L4 are wound around the rod-shaped core RC one over the other (the coil shown by a solid line corresponds to the third inductor L3, and the coil shown by a broken line corresponds to the fourth inductor L4). However, the two coils L3 and L4 are wound in the opposite directions around the rod-shaped core RC, in contrast to bifilar windings. In any of FIGS. 10, 11, and 12, as shown in FIG. 9, lines between the normal mode choke 3 and the input terminals 1a, 1b, the output terminals 3a, 3b of the filter circuit 1 are shorter than the lines shown in FIGS. 7 and 8. This is accordingly advantage in miniaturization of the filter circuit 1.

In the filter circuit 1 according to Embodiment 1 of the present invention, the common mode choke 2 has sufficiently high impedance for common mode signals, and sufficiently low impedance for differential signals. Conversely, the normal mode choke 3 has sufficiently low impedance for common mode signals, and sufficiently high impedance for differential signals. In particular, the differences of the impedances are sufficiently large. Furthermore, the normal mode choke 3 is located at a stage prior to the common mode choke 2, and in other words, connected to a place nearer to the first input terminal 1a and the second input terminal 1b than the common mode choke 2 (cf. FIGS. 7, 8, and 9). Accordingly, of differential signals received through the first input terminal 1a and the second input terminal 1b, only normal mode components are substantially allowed to penetrate the common mode choke 2, and only common mode components are substantially allowed to penetrate the normal mode choke 3. Thus, both components are separated from the differential signals. In particular, common-mode noises received through the first input terminal 1a and the second input terminal 1b are cut off from the first output terminal 1a and the second output terminal 1b. In addition, substantial common-mode noises are not reflected by the common mode choke 2. Moreover, substantial common mode currents do not flow in the common mode choke 2, and thus, the core of the common mode choke 2 does not become magnetically saturated. Therefore, the filter circuit 1 has a high degree of reliability.

In the differential receiving device 10 (and the differential transmitting and receiving device 30) shown in FIGS. 2 and 3, the filter circuit 1 allows substantially all normal mode components of the differential signals received through the cable 40 to penetrate completely. Accordingly, for normal mode components of the differential signals, impedance matching among the differential receiver 11 (31), the differential line 12 (33), and the cable 40 reduces substantial distortion and attenuation of the differential signals, as described above (cf. FIGS. 4, 5). In addition, the impedance matching add no severe constraints to the layout of the differential line 12 (33), and thus, the differential receiving device 10 (the differential transmitting and receiving device 30) has a high degree of flexibility in circuit design. In the filter circuit 1, the normal mode choke 3 further absorbs substantially all common-mode noises. Accordingly, the differential receiver 11 and its following stage circuits (the differential receiver 31 and its following stage circuits, and the differential driver 32) are reliably protected from common-mode noises. Furthermore, substantial reflection of common-mode noises by the common mode choke 2 is completely suppressed. Therefore, EMI radiations from the cable 40 to the surroundings are sufficiently reduced.

Note that, in the differential receiving device 10 shown in FIGS. 2 and 3, the input impedance of the differential receiver 11, which is connected to the first output terminal 2a and the second output terminal 2b, is sufficiently higher than the impedance of the normal mode choke 3, for common mode signals. In that case, the common mode chokes 2 may be eliminated from the filter circuit 1 (cf. FIG. 13). The common-mode noises coming from the two input terminals 1a and 1b penetrates the normal mode choke 3, and then, is not transmitted from the two output terminals 2a and 2b to the differential receiver 11.

In the differential transmitting device 20 shown in FIGS. 2 and 3, the filter circuit 1 allows substantially all normal mode components of the differential signals sent out from the differential driver 21 to penetrate completely. Accordingly, for normal mode components of the differential signals, impedance matching among the differential driver 21, the differential line 22, and the cable 40 reduces substantial distortion and attenuation of the differential signals, as described above (cf. FIG. 6). In addition, the impedance matching add no severe constraints to the layout of the differential line 22, and thus, the differential transmitting device 20 has a high degree of flexibility in circuit design. In the filter circuit 1, the normal mode choke 3 further absorbs substantial common-mode noises caused by the differential driver 21 or the differential line 22. Accordingly, EMI radiations from the cable 40 to the surroundings are sufficiently reduced. Furthermore, substantial reflection of common-mode noise by the common mode choke 2 is completely suppressed. Therefore, the differential driver 21 is reliably protected from common-mode noises reflected by the common mode choke 2.

### Embodiment 2

A differential transmission system according to Embodiment 2 of the present invention is preferably installed into an in-car LAN, like the system according to Embodiment 1. Embodiment 2 of the present invention differs from Embodiment 1 in the way that a filter circuit 1 includes a multilayer inductor or a thin film inductor. A description of components according to Embodiment 2 of the present invention that are similar to components according to Embodiment 1, can be found above in the description of Embodiment 1.

The filter circuit 1 according to Embodiment 2 of the present invention is expressed by an equivalent circuit similar to that of the filter circuit according to Embodiment 1 (cf. FIG. 14). However, all inductors L1, L2, L3, and L4, which are included in a common mode choke 2 and a normal mode choke 3, are multilayer inductors or thin film inductors, and they are integrated in the same chip 2B (cf. FIGS. 15, 16, and 17), in contrast to the filter circuit according to Embodiment 1. Thereby, the filter circuit 1 according to Embodiment 2 of the present invention is extremely small. In this case, first and second input terminals 1a, 1b, and first to fourth output terminals 2a, 2b, 3a, and 3b are preferably installed in the same plane as the surface of the chip 2B. Alternatively, any of or all of those terminals may be installed in a plane perpendicular to the chip 2B.

The filter circuit 1 preferably includes twelve laminated magnetic material sheets (hereinafter, layers) S1, S2, . . . and S12 (cf. FIG. 15). Here, the magnetic material sheets are preferably ceramic sheets. Conducting traces (preferably, metallic foil) C1, C2, . . . and C12 are formed on each layer S1, S2, . . . and S12, preferably by using screen printing, or alternatively, by sputtering or vapor deposition. Hereafter, the layers are referred to as a first layer S1, a second layer S2, . . . , in the order from top to bottom.

Three layers from the first layer S1 to the third layer S3 correspond to the first inductor L1 (cf. FIG. 15). A second via hole V2 connects the conducting trace C1 on the first layer S1 with the conducting trace C2 on the second layer S2, and a third via hole V3 connects the conducting trace C2 on the second layer S2 with the conducting trace C3 on the third layer S3. Thereby, the three conducting traces C1, C2, and C3 form a rectangular coil that is wound approximately (2+¼) turns clockwise with respect to the direction of a normal N passing from the third layer S3 to the first layer S1 (cf. FIG. 16). One end T1A of the conducting trace C1 on the first layer S1 is connected to the first input terminal 1a, and one end T2A of the conducting trace C3 on the third layer S3 is connected to the first output terminal 2a (cf. FIG. 14).

Three layers from the fourth layer S4 to the sixth layer S6 correspond to the second inductor L2 (cf. FIG. 15). A fifth via hole V5 connects the conducting trace C4 on the fourth layer S4 with the conducting trace C5 on the fifth layer S5, and a sixth via hole V6 connects the conducting trace C5 on the fifth layer S5 with the conducting trace C6 on the sixth layer S6. Thereby, the three conducting traces C4, C5, and C6 form a rectangular coil that is wound approximately (2+¾) turns clockwise with respect to the direction of a normal N passing from the fourth layer S4 to the sixth layer S6 (cf. FIG. 16). One end T1B of the conducting trace C4 on the fourth layer S4 is connected to the second input terminal 1b, and one end T2B of the conducting trace C6 on the sixth layer S6 is connected to the second output terminal 2b (cf. FIG. 14).

Three layers from the seventh layer S7 to the ninth layer S9 correspond to the third inductor L3 (cf. FIG. 15). A seventh via hole V7 connects the conducting trace C7 on the seventh layer S7 with the conducting trace C8 on the eighth layer S8, and an eighth via hole V8 connects the conducting trace C8 on the eighth layer S8 with the conducting trace C9 on the ninth layer S9. Thereby, the three conducting traces C7, C8, and C9 form a rectangular coil that is wound approximately (2+⅛) turns clockwise with respect to the direction of a normal N passing from the ninth layer S9 to the seventh layer S7 (cf. FIG. 16). One end of the conducting trace C7 on the seventh layer S7 is connected to the end T1A of the conducting trace C1 on the first layer S1 through the first via hole V1, accordingly connected to the first input terminal 1a (cf. FIG. 14). One end T3A of the conducting trace C9 on the ninth layer S9 is connected to the third output terminal 3a, accordingly maintained at a fixed potential (preferably, a ground potential) (cf. FIG. 14).

Three layers from the tenth layer S10 to the twelfth layer S12 correspond to the fourth inductor L4 (cf. FIG. 15). A ninth via hole V9 connects the conducting trace C10 on the tenth layer S10 with the conducting trace C11 on the eleventh layer S11, and a tenth via hole V10 connects the conducting trace C11 on the eleventh layer S11 with the conducting trace C12 on the twelfth layer S12. Thereby, the three conducting traces C10, C11, and C12 form a rectangular coil that is wound approximately (2+⅛) turns counterclockwise with respect to the direction of a normal N passing from the twelfth layer S12 to the tenth layer S10 (cf. FIG. 16). One end of the conducting trace C10 on the tenth layer S10 is connected to the end T1B of the conducting trace C4 on the fourth layer S4 through the fourth via hole V4, accordingly connected to the second input terminal 1b (cf. FIG. 14). One end T3B of the conducting trace C12 on the twelfth layer S12 is connected to the fourth output terminal 3b, accordingly maintained at a fixed potential (preferably, a ground potential) (cf. FIG. 14).

Another magnetic material sheet S0 is put on the first layer S1 (cf. FIG. 17). Magnetic materials of all the layers are merged by adding heat to the entirety of the laminated magnetic material sheets. Thereby, the coil C1, C2, and C3 running from the first layer S1 to the third layer S3 magnetically couples to the coil C4, C5, and C6 running from the fourth layer S4 to the sixth layer S6, through the merged magnetic materials used as a core. In particular, both coils are wound in the same direction around the normal N, and accordingly, the first layer S1 through the sixth layer S6, that is, the first inductor L1 and the second inductor L2 form a common mode choke 2. Similarly, the coil C7, C8, and C9 running from the seventh layer S7 to the ninth layer S9 magnetically couples to the coil C10, C11, and C12 running from the tenth layer S10 to the twelfth layer S12, through the merged magnetic materials used as a core. In particular, the coils are wound in the opposite directions around the normal N, and accordingly, the seventh layer S7 through the twelfth layer S12, that is, the third inductor L3 and the fourth inductor L4 form a normal mode choke 3.

Like the filter circuit according to Embodiment 1, the filter circuit according to Embodiment 2 of the present invention allows substantially all normal mode components of differential signals received through the first input terminal 1a and the second input terminal 1b, to penetrate the common mode choke 2, and allows substantially all common mode components of the differential signals to penetrate the normal mode choke 3. Thus, the components are separated from the differential signals. In particular, common-mode noises received through the first input terminal 1a and the second input terminal 1b are cut off from the first output terminal 1a and the second output terminal 1b. In addition, substantially all the common-mode noises are not reflected by the common mode choke 2. Moreover, substantial common mode currents do not flow in the common mode choke 2, and thus, the core of the common mode choke 2 does not become magnetically saturated. Therefore, the filter circuit 1 has a high degree of reliability. In particular, the core of the common mode choke 2 may have a low volume, and accordingly, the common mode choke 2 is allowed to be composed of the multilayer inductors (or, the thin film inductors) as described above.

Note that the number of the layers and the number of turns of the conducting traces may be different from those shown in FIG. 15. Furthermore, the shape of the coil may be a circle or another polygon, in contrast to the rectangle shown in FIGS. 15 and 16. However, it is desirable that the turn number and shape of the coil C1, C2, and C3 included in the first inductor L1 accurately matches with those of the coil C4, C5, and C6 included in the second inductor L2. Similarly, it is desirable that the turn number and shape of the coil C7, C8, and C9 included in the third inductor L3 accurately matches with those of the coil C10, C11, and C12 included in the fourth inductor L4. Thereby, a high balance is maintained between the first input terminal 1a and the second input terminal 1b, and therefore, no distortion occur in the differential signals that penetrates the filter circuit 1. Alternatively, the end T3A of the conducting trace C9 on the ninth layer S9 and the end T3B of the conducting trace C12 on the twelfth layer S12, in contrast to those shown in FIGS. 15 and 16, may be located at the same distance from the end T1A of the conducting trace C1 on the first layer S1 and the end T1B of the conducting trace C4 on the fourth layer S4 (see, for example, portions T3D and T3E shown by the alternate long and short dash lines in FIG. 16). Thereby, a high balance is maintained between the first input terminal 1a and the second input terminal 1b, and therefore, no distortion occur in the differential signals that penetrates the filter circuit 1.

In the common mode choke 2, in contrast to that shown in FIGS. 15 and 17, the three layers S1, S2, and S3 that constitute the first inductor L1, and the three layers S4, S5, and S6 that constitute the second inductor L2, may be alternately laminated (cf. FIGS. 18, 19). Thereby, the conducting traces C1, C2, and C3 included in the first inductor L1 and the conducting traces C4, C5, and C6 included in the second inductor have equal spacing and equal parasitic capacitance that depends on the spacing, for example (cf. FIG. 19). As a result, the balance is further improved in lines for the differential signals included in the filter circuit 1. Accordingly, no distortion occurs in the differential signals that penetrate the filter circuit 1. Note that, in the normal mode choke 3, the three layers S7, S8, and S9 that constitute the third inductor L3, and the three layers S10, S11, and S12 that constitute the fourth inductor L4, may be alternately laminated (not shown in the figures), in a similar manner to that of the common mode choke 2.

The six layers S7-S12 that constitute the normal mode choke 3 may be formed on the six layers S1-S6 that constitute the common mode choke 2. A magnetic separation layer Ss may be inserted between the common mode choke 2 and the normal mode choke 3, for example, between the sixth layer S6 and the seventh layer S7 (cf. FIG. 20). The magnetic separation layer Ss is preferably a magnetic material sheet, on which a conductor film GND is formed. The conductor film GND uniformly covers the whole area that is surrounded by the conducting traces C1, . . . , C12 on the respective layers S1, . . . , S12. Alternatively, the conductor film GND may be a mesh conductor film spread over the whole area. The conductor film GND is maintained at a fixed potential (preferably, a ground potential). Thereby, the conductor film GND does not allow magnetic fields to penetrate, and accordingly, magnetically separates the common mode choke 2 and the normal mode choke 3. As a result, the common mode choke 2 and the normal mode choke 3 do not interfere with each other, and accordingly, both of them have a higher degree of reliability.

In order to reduce magnetic interference between the common mode choke 2 and the normal mode choke 3, the two chokes 2 and 3 may be formed in the separate regions on magnetic material sheets (cf. FIGS. 21, 22, and 23), instead of the insertion of the magnetic separation layer Ss (cf. FIG. 20). The right halves of seven magnetic material sheets S1, S2, . . . , and S7 shown in FIGS. 21, 22, and 23 correspond to the common mode choke 2, and the left halves of them correspond to the normal mode choke 3.

The second via hole V2 connects between the first conducting trace C1 on the first layer S1 and the first conducting trace C3 on the third layer S3, and the third via hole V3 connects between the first conducting trace C3 on the third layer S3 and the conducting trace C5 on the fifth layer S5. Thereby, the three first conducting traces C1, C3, and C5 form a rectangular coil that is wound approximately (2+½) turns clockwise with respect to the direction of a first normal N1 passing from the fifth layer S5 to the first layer S1 (cf. FIG. 21). The first coil C1, C3, and C5 corresponds to the first inductor L1. One end T1A of the first conducting trace C1 on the first layer S1 is connected to the first input terminal 1a, and one end T2A of the first conducting trace C5 on the fifth layer S5 is connected to the first output terminal 2a (cf. FIG. 14).

The fifth via hole V5 connects between the second conducting trace C7 on the first layer S1 and the first conducting trace C2 on the second layer S2; the sixth via hole V6 connects between the first conducting trace C2 on the second layer S2 and the first conducting trace C4 on the fourth layer S4; and the seventh via hole V7 connects between the first conducting trace C4 on the fourth layer S4 and the first conducting trace C6 on the sixth layer S6. Thereby, the three first conducting traces C2, C4, and C6 form a rectangular coil that is wound approximately (2+½) turns clockwise with respect to the direction of the first normal N1 passing from the sixth layer S6 to the first layer S1 (cf. FIG. 21). This second coil C2, C4, and C6 correspond to the second inductor L2. One end T1B of the second conducting trace C7 on the first layer S1 is connected to the second input terminal 1b, and one end T2B of the first conducting trace C6 on the sixth layer S6 is connected to the second output terminal 2b (cf. FIG. 14).

The first via hole V1 connects between the first conducting trace C1 on the first layer S1 and the second conducting trace C8 on the second layer S2, the eighth via hole V8 connects between the second conducting trace C8 on the second layer S2 and the second conducting trace C10 on the fourth layer S4, and the ninth via hole V9 connects between the second conducting trace C10 on the fourth layer S4 and the second conducting trace C12 on the sixth layer S6. Thereby, the three second conducting traces C8, C10, and C12 form a rectangular coil that is wound approximately (2+¾) turns clockwise with respect to the direction of a second normal N2 passing from the sixth layer S6 to the first layer S1 (cf. FIG. 21). The third coil C8, C10, and C12 correspond to the third inductor L3. One end T3A of the second conducting trace C12 on the sixth layer S6 is connected to the third output terminal 3a, accordingly maintained at a fixed potential (preferably, a ground potential) (cf. FIG. 14).

The fourth via hole V4 connects between the second conducting trace C7 on the first layer S1 and the second conducting trace C9 on the third layer S3, the tenth via hole V10 connects between the second conducting trace C9 on the third layer S3 and the second conducting trace C11 on the fifth layer S5, and the eleventh via hole V11 connects between the second conducting trace C11 on the fifth layer S5 and the conducting trace C13 on the seventh layer S7. Thereby, the three conducting traces C9, C11, and C13 form a rectangular coil that is wound approximately (2+¾) turns counterclockwise with respect to the direction of the second normal N2 passing from the seventh layer S7 to the first layer S1 (cf. FIG. 21). The fourth coil C9, C11, and C13 correspond to the fourth inductor L4. One end T3B of the conducting trace C13 on the seventh layer S7 is connected to the fourth output terminal 3b, accordingly maintained at a fixed potential (preferably, a ground potential) (cf. FIG. 14).

Another magnetic material sheet S0 is put on the first layer S1 (cf. FIG. 23). Magnetic materials of all the layers are merged by adding heat to the entirety of the laminated magnetic material sheets. Thereby, the first coil C1, C3, and C5 magnetically couples to the second coil C2, C4, and C6 through the merged magnetic materials used as a core. In particular, both coils are wound in the same direction around the first normal N1, and accordingly, the first inductor L1 and the second inductor L2 form the common mode choke 2. Similarly, the third coil C8, C10, and C12 magnetically couples to the fourth coil C9, C11, and C13 through the merged magnetic materials used as a core. In particular, the coils are wound in the opposite directions around the second normal N2, and accordingly, the third inductor L3 and the fourth inductor L4 form the normal mode choke 3.

As it is clear from FIGS. 21, 22, and 23, the magnetic fluxes caused by the first and second coils C1-C6 hardly interact with the magnetic fluxes caused by the third and fourth coils C8-C13. Accordingly, the common mode choke 2 and the normal mode choke 3 are magnetically separated. As a result, the common mode choke 2 and the normal mode choke 3 do not interfere with each other, and therefore, both of them have a higher degree of reliability.

Note that the number of the layers and the number of turns of the conducting traces may be different from those shown in FIG. 21. Furthermore, the shape of the coil may be a circle or another polygon, in contrast to the rectangle shown in FIGS. 21 and 22. However, it is desirable that the turn number and shape of the first coil C1, C2, and C3 accurately matches with those of the second coil C4, C5, and C6. Similarly, it is desirable that the turn number and shape of the third coil C8, C10, and C12 accurately matches with those of the fourth coil C9, C11, and C13. Thereby, a high balance is maintained between the first input terminal 1a and the second input terminal 1b, and therefore, no distortions occur in the differential signals that penetrate the filter circuit 1. Alternatively, the end T3A of the second conducting trace C12 on the sixth layer S6 and the end T3B of the conducting trace C13 on the seventh layer S7, in contrast to those shown in FIGS. 21 and 22, may be located at the same distance from the end T1A of the first conducting trace C1 and the end T1B of the second conducting trace C7 on the first layer S1. Thereby, a high balance is maintained between the first input terminal 1a and the second input terminal 1b, and therefore, no distortions occur in the differential signals that penetrate the filter circuit 1.

In the equivalent circuit of the filter circuit 1 shown in FIG. 14, the third output terminal 3a and the fourth output terminal 3b are separated terminals. Alternatively, a common output terminal 3c may double as the third output terminal 3a and the fourth output terminal 3b (cf. FIG. 24). Thereby, the number of terminals of the filter circuit 1 is reduced, and accordingly, the circumference circuit design has a higher degree of flexibility. For example, the eleventh via hole V11 connects a conducting trace C9A on the ninth layer S9 to a conducting trace C12A on the twelfth layer S12 (cf. FIG. 25), in contrast to the filter circuit 1 shown in FIGS. 15, 16, and 17. Furthermore, one end T3C of the conducting trace C12A on the twelfth layer S12 is connected to the common output terminal 3c, and then maintained at a fixed potential (preferably, a ground potential). Here, the end T3C of the conducting trace C12A on the twelfth layer S12 is located at the same distance from the end T1A of the conducting trace C1 on the first layer S1 and the end T1B of the conducting trace C4 on the fourth layer S4 (cf. FIG. 26). Thereby, a high balance is maintained between the first input terminal 1a and the second input terminal 1b, and therefore, no distortions occur in the differential signals that penetrate the filter circuit 1.

### Embodiment 3

A differential transmission system according to Embodiment 3 of the present invention is preferably installed into an in-car LAN, like the system according to Embodiment 1. Embodiment 3 of the present invention differs from Embodiments 1, 2 in the way that a filter circuit 1 includes a terminator element. A description of components according to Embodiment 3 of the present invention that are similar to components according to Embodiment 1 or 2, can be found above in the description of Embodiment 1 or 2.

The filter circuit 1 according to Embodiment 3 of the present invention is expressed by an equivalent circuit similar to that of the filter circuit 1 according to Embodiment 1 (cf. FIGS. 27, 28, 29, 30, 31). However, terminator elements Z1 and Z2 are connected to a normal mode choke 3, in contrast to the filter circuit 1 according to Embodiment 1. The terminator elements Z1 and Z2 are impedance elements, preferably capacitors, or alternatively, may be inductors, varistors, diodes, resistance elements, or combinations thereof.

When the normal mode choke 3 is an element that is separated from the common mode choke 2, preferably, the first terminator element Z1 is connected between the third inductor L3 and a third output terminals 3a, and the second terminator element Z2 is connected between the fourth inductor L4 and the fourth output terminal 3b (cf. FIG. 27). Alternatively, the first terminator element Z1 may be connected between the first input terminal 1a and the third inductor L3, and the second terminator element Z2 may be connected between the second input terminal 1b and the fourth inductor L4 (cf. FIG. 28).

When a common mode choke array 2A that includes two common mode chokes is used as a combination of a common mode choke 2 and a normal mode choke 3, the first terminator element Z1 is connected between the third inductor L3 and the third output terminals 3a, and the second terminator element Z2 is connected between the fourth inductor L4 and the fourth output terminal 3b (cf. FIG. 29). Furthermore, the first terminator element Z1 may be connected between the first input terminal 1a and the third inductor L3, and the second terminator element Z2 may be connected between the second input terminal 1b and the fourth inductor L4 (see the parts represented by broken lines in FIG. 29).

When the common mode choke 2 and the normal mode choke 3 are constructed by multilayer inductors (or thin film inductors), like Embodiment 2 of the present invention, the first terminator element Z1 is connected between one end T3A of the third inductor L3 and the third output terminal 3a, and the second terminator element Z2 is connected between one end T3B of the fourth inductor L4 and the fourth output terminal 3b (cf. FIGS. 14, 30). Furthermore, when a common output terminal 3c doubles as the third output terminal 3a and the fourth output terminal 3b, the first terminator element Z1 and the second terminator element Z2 are combined into a single terminator element Z, which is connected between the common output terminal 3c and a common end T3C of the third inductor L3 and the fourth inductor L4 (cf. FIGS. 24, 31).

For common mode signals received through the first input terminal 1a and the second input terminal 1b, the impedance of the common mode choke 2 is extremely high, and the impedance of the normal mode choke 3 is extremely low. Accordingly, in the differential receiving device 10 (and, the differential transmitting and receiving device 30) shown in FIGS. 2 and 3, each impedance of the first terminator element Z1 and the second terminator element Z2 (in FIG. 31, the impedance of the integrated terminator element Z) is adjusted to match the common mode impedance of the cable 40. For example, when the common mode impedance of the cable 40 is 30Ω, each impedance of the first terminator element Z1 and the second terminator element Z2 is set at about 60Ω (in FIG. 31, the impedance of the integrated terminator element Z is set at about 30 Ω). Thus, impedance matching for common mode signals is realized between the cable 40 and the filter circuit 1 with high precision, and then, the reflection of common-mode noises by the common mode choke 2 is further reduced. Therefore, EMI radiations from the cable 40 to the vicinity thereof are further reduced.

Similarly, in the differential transmitting device 20 shown in FIGS. 2 and 3, each impedance of the first terminator element Z1 and the second terminator element Z2 (in FIG. 31, the impedance of the integrated terminator element Z) is adjusted to match the common mode impedance of the differential line 22. For example, when the common mode impedance of the differential line 22 is 30Ω, each impedance of the first terminator element Z1 and the second terminator element Z2 is set at about 60Ω (in FIG. 31, the impedance of the integrated terminator element Z is set at about 30Ω). Thus, impedance matching for common mode signals is realized between the differential line 22 and the filter circuit 1 with high precision, and then, the reflection of common-mode noises by the common mode choke 2 is further reduced. Therefore, common-mode noises are prevented from penetrating the LSI that includes the differential driver 21, and further from penetrating the previous stage circuits, and accordingly, the power potential and the ground potential reliably avoid fluctuations caused by the reflected common-mode noises.

When the first terminator element Z1 and the second terminator element Z2 are inductors, each impedance of them changes with the frequencies of the differential signals (in general, it reaches a peak at a specific frequency called a self-resonant frequency). The frequency characteristic of the impedance is used for adjustment of the frequency characteristic of the common mode impedance, into which the first terminator element Z1 and the second terminator element Z2 are combined. For example, there is a case where common mode signals are transmitted through a differential line, such as the case where speed signals (signals for comparing transfer rates between communications appliances) are used in IEEE 1394. In that case, the above-described common mode impedance is adjusted to be sufficiently high within the frequency band of the common mode signals, and to be sufficiently low outside of the frequency band. Thereby, common-mode noises are eliminated without excessive distortion and attenuation of the above-described common mode signals.

When the first terminator element Z1 and the second terminator element Z2 are capacitors, each impedance of the terminator elements is sufficiently high in low-frequency bands of the common mode components of differential signals (which, in particular, includes a bias voltage), and is sufficiently low in high-frequency bands of the common mode components. When the differential transmission system shown in FIGS. 2 and 3 uses a bias voltage, the above impedance characteristic can be used for protection from a shorts of the filter circuit 1 to a fixed potential terminal through the third output terminal 3a and the fourth output terminal 3b.

In the case where the first terminator element Z1 and the second terminator element Z2 are varistors or diodes, each impedance of the terminator elements abruptly drops when a common-mode noise exceeds a predetermined level. This impedance characteristic allows the filter circuit 1 to short the first input terminal 1a and the second input terminal 1b to a fixed potential terminal, when the level of a common-mode noise exceeds a predetermined level (for example, a level sufficiently higher than a bias voltage). Thereby, destruction of circuit elements caused by excessive common-mode noises and occurrence of excessive EMI radiations can be prevented.

### Embodiment 4

A differential transmission system according to Embodiment 4 of the present invention is preferably installed into an in-car LAN, like the system according to Embodiment 1. Embodiment 4 of the present invention differs from Embodiment 1 in the way that a filter circuit 1 includes a second normal mode choke 4. A description of components according to Embodiment 4 of the present invention that are similar to components according to Embodiment 1, can be found above in the description of Embodiment 1.

The filter circuit 1 further comprises a fifth output terminal 4a, a sixth output terminal 4b, and a second normal mode choke 4 (cf. FIG. 32). The fifth output terminal 4a and the sixth output terminal 4b are connected to a fixed potential terminal (preferably, a ground terminal).

The second normal mode choke 4 includes two inductors L5 and L6. The fifth inductor L5 is connected between the first output terminal 2a and the fifth output terminal 4a. The sixth inductor L6 is connected between the second output terminal 2b and the sixth output terminal 4b. The two inductors L5 and L6 magnetically couple to each other, and in particular, they are connected between the input terminals and the output terminals in the opposite polarities. In other words, when a normal mode current flows between the first and second output terminals 2a, 2b and the fifth and sixth output terminals 4a, 43b, magnetic fluxes which appear in the two inductors L5 and L6 enhance each other, and when a common mode current flows between the first and second output terminals 2a, 2b and the fifth and sixth output terminals 4a, 4b, magnetic fluxes which appear in the two inductors L5 and L6 cancel each other out. Thereby, the impedance of the second normal mode choke 4 is extremely high for the normal mode components of the signals received through the first and second output terminals 2a, 2b, and is extremely low for the common mode components of the signals.

The second normal mode choke 4 includes a single core and two coils that are wound around the core in Embodiment 4 of the present invention. Preferably, the two coils are wound around the core in the directions of windings of a bifilar or cancel coil. In other words, the second normal mode choke 4 has the same configuration as the common mode choke 2. In that case, as shown in FIG. 32, the fifth inductor L5 and the sixth inductor L6 have opposite polarities in the connection to the respective input/output terminals. More preferably, a common mode choke array 2C that includes three common mode chokes is used as a combination of the common mode choke 2, the normal mode choke 3, and the second normal mode choke 4 according to Embodiment 4 of the present invention (cf. FIG. 33). Thereby, the common mode choke 2 and the two normal mode chokes 3, 4 are integrated into a single package, and this offers an advantage in miniaturization of the filter circuit 1.

In another second normal mode choke 4, like the normal mode choke 3, two coils may be wound around the core in the directions so that the magnetic fluxes caused by common mode currents cancel each other out (cf. FIG. 9). In other words, one of the two coils is wound in the reversed direction of windings of a bifilar or cancel coil (cf. FIGS. 10, 11, and 12). In any of FIGS. 10, 11, and 12, lines between the second normal mode choke 4 and the output terminals 2a, 2b, 4a, 4b of the filter circuit 1 are shorter than the lines shown in FIG. 32 (cf. FIG. 9). This is accordingly advantage in miniaturization of the filter circuit 1.

As shown in FIG. 32, the normal mode choke 3 and the second normal mode choke 4 are arranged symmetrically with respect to the common mode choke 2 between the side of the first input terminal 1a and the second input terminal 1b, and the side of the first output terminal 2a and the second output terminal 2b in the filter circuit 1 according to Embodiment 4 of the present invention. Furthermore, impedance characteristics are symmetrical between the normal mode choke 3 and the second normal mode choke 4. More specifically, like the impedance of the normal mode choke 3, the impedance of the second normal mode choke 4 is sufficiently low for common mode signals, and sufficiently high for differential signals. In particular, the difference of those impedances is sufficiently large.

Of differential signals received through the first input terminal 1a and the second input terminal 1b, limited common mode components that was allowed to penetrate the common mode choke 2, are allowed to penetrate the second normal mode choke 4. Thus, common-mode noises received through the first input terminal 1a and the second input terminal 1b are more reliably cut off from the first output terminal 2a and the second output terminal 2b. Conversely, of differential signals received through the first output terminal 2a and the second output terminal 2b, normal mode components are allowed to penetrate the common mode choke 2, and common mode components are allowed to penetrate the second normal mode choke 4. Furthermore, limited common mode components that was allowed to penetrate the common mode choke 2, are allowed to penetrate the normal mode choke 3. Thus, common-mode noises received through the first output terminal 2a and the second output terminal 2b are reliably cut off from the first input terminal 1a and the second input terminal 1b. In addition, substantial common-mode noises are not reflected by the common mode choke 2 toward the first output terminal 2a and the second output terminal 2b. Moreover, substantial common mode currents do not flow in the common mode choke 2, and thus, the core of the common mode choke 2 does not become magnetically saturated. Therefore, the filter circuit 1, which is served as a two-way common-mode noise filter, has a high degree of reliability.

In the differential receiving device 10 shown in FIGS. 2 and 3, the filter circuit 1 allows substantially all normal mode components of the differential signals received through the cable 40 to penetrate completely. Accordingly, for normal mode components of the differential signals, impedance matching between the differential receiver 11, the differential line 12, and the cable 40 reduces substantial distortion and attenuation of the differential signals (cf. FIGS. 4, 5). Furthermore, the impedance matching adds no severe constraints to the layout of the differential line 12, and thus, the differential receiving device 10 has a high degree of flexibility in circuit design. In the filter circuit 1, the two normal mode chokes 3, 4 further absorb substantially all common-mode noises at the previous and next stages of the common mode choke 2, respectively. Therefore, the differential receiver 11 and its following stage circuits are reliably protected from common-mode noises. In addition, substantial reflection of common-mode noises by any of the common mode choke 2, the differential line 12, and the differential receiver 11 is completely suppressed. Thus, EMI radiations from the cable 40 and the differential line 12 to the surroundings reduce sufficiently.

In the differential transmitting device 20 shown in FIGS. 2 and 3, the filter circuit 1 allows substantially all normal mode components of the differential signals sent out from the differential driver 21 to penetrate completely. Accordingly, for normal mode components of the differential signals, impedance matching among the differential driver 21, the differential line 22, and the cable 40 reduces substantial distortion and attenuation of the differential signals (cf. FIG. 6). Furthermore, the impedance matching adds no severe constraints to the layout of the differential line 22, and thus, the differential transmitting device 20 has a high degree of flexibility in circuit design. In the filter circuit 1, the two normal mode chokes 3, 4 further absorb substantially all common-mode noises at the previous and next stages of the common mode choke 2, respectively. Therefore, EMI radiations from the differential line 22 and the cable 40 to the surroundings reduce sufficiently. In addition, the differential driver 21 is reliably protected from both common-mode noises reflected by the common mode choke 2 and received through the cable 40.

In the differential transmitting and receiving device 30 shown in FIGS. 2 and 3, the filter circuit 1 allows substantially all normal mode components of the differential signals to pass in opposite directions between the differential line 33 and the cable 40. Accordingly, for normal mode components of the differential signals, impedance matching among the differential receiver 31, the differential line 33, and the cable 40 reduces substantial distortion and attenuation of the differential signals (cf. FIGS. 4, 5). Furthermore, the impedance matching adds no severe constraints to the layout of the differential line 33, and thus, the differential transmitting and receiving device 30 has a high degree of flexibility in circuit design. In the filter circuit 1, the two normal mode chokes 3, 4 further absorb substantially all common-mode noises at the previous and next stages of the common mode choke 2, respectively. Therefore, the differential receiver 31, its following stage circuits, and the differential driver 32 are reliably protected from common-mode noises. In addition, EMI radiations from the differential line 33 and the cable 40 to the surroundings reduce sufficiently.

### Embodiment 5

A differential transmission system according to Embodiment 5 of the present invention is preferably installed into an in-car LAN, like the system according to Embodiment 4. Embodiment 5 of the present invention differs from Embodiment 4 in the way that a filter circuit 1 includes a multilayer inductor or a thin film inductor. A description of components according to Embodiment 5 of the present invention that are similar to components according to Embodiment 4, can be found above in the description of Embodiment 4.

The filter circuit 1 according to Embodiment 5 of the present invention is expressed by an equivalent circuit similar to that of the filter circuit according to Embodiment 4 (cf. FIG. 34). However, all inductors L1, L2, L3, L4, L5, and L6, which are included in a common mode choke 2, a normal mode choke 3, and a second normal mode choke 4, are multilayer inductors or thin film inductors, and they are integrated in the same chip 2D (cf. FIGS. 35, 36, and 37), in contrast to the filter circuit according to Embodiment 4. Thereby, the filter circuit 1 according to Embodiment 5 of the present invention is extremely small. In this case, first and second input terminals 1a, 1b, and first to sixth output terminals 2a, 2b, 3a, 3b, 4a, and 4b are preferably installed in the same plane as the surface of the chip 2D. Alternatively, any of or all of those terminals may be installed in a plane perpendicular to the chip 2D.

The filter circuit 1 preferably includes eighteen laminated magnetic material sheets (hereinafter, layers) S1, S2, . . . S12, S13, S14, . . . and S18 (cf. FIG. 35). Here, the magnetic material sheets are preferably ceramic sheets. Hereinafter, the layers are referred to as a first layer S1, a second layer S2, . . . , in the order from top to bottom. The first layer S1 through the twelfth layer S12 of the filter circuit 1 have a structure quite similar to the structure of the filter circuit according to Embodiment 1 of the present invention shown in FIG. 15. Accordingly, the description of details of the structure can be found above in the description of Embodiment 1. Note that a coil C7, C8, and C9 from the seventh layer S7 to the ninth layer S9 form a rectangular coil that is wound approximately (2+¼) turns, and a coil C10, C11, and C12 from the tenth layer S10 to the twelfth layer S12 form a rectangular coil that is wound approximately (2+¼) turns (cf. FIG. 36).

Conducting traces (preferably, metallic foil) C13, C14, . . . and C18 are formed on each of the thirteenth layer S13 through the eighteenth layer S18, preferably by using screen printing, or alternatively, by sputtering or vapor deposition.

Three layers from the thirteenth layer S13 to the fifteenth layer S15 correspond to the fifth inductor L5 (cf. FIG. 35). A twelfth via hole V12 connects between the conducting trace C13 on the thirteenth layer S13 and the conducting trace C14 on the fourteenth layer S14, and a thirteenth via hole V13 connects between the conducting trace C14 on the fourteenth layer S14 and the conducting trace C15 on the fifteenth layer S15. Thereby, the three conducting traces C13, C14, and C15 form a rectangular coil that is wound approximately (2+¼) turns counterclockwise with respect to the direction of a normal N passing from the fifteenth layer S15 to the thirteenth layer S13 (cf. FIG. 36). One end of the conducting trace C13 on the thirteenth layer S13 is connected to the end T2A of the conducting trace C3 on the third layer S3 through an eleventh via hole V11, accordingly connected to the first output terminal 2a (cf. FIG. 34). One end T4A of the conducting trace C15 on the fifteenth layer S15 is connected to the fifth output terminal 4a, accordingly maintained at a fixed potential (preferably, a ground potential) (cf. FIG. 34).

Three layers from the sixteenth layer S16 to the eighteenth layer S18 correspond to the sixth inductor L6 (cf. FIG. 35). A fifteenth via hole V15 connects between the conducting trace C16 on the sixteenth layer S16 and the conducting trace C17 on the seventeenth layer S17, and a sixteenth via hole V16 connects between the conducting trace C17 on the seventeenth layer S17 and the conducting trace C18 on the eighteenth layer S18. Thereby, the three conducting traces C16, C17, and C18 form a rectangular coil that is wound approximately (2+¼) turns clockwise with respect to the direction of a normal N passing from the eighteenth layer S18 to the sixteenth layer S16 (cf. FIG. 36). One end of the conducting trace C16 on the sixteenth layer S16 is connected to one end T4B of the conducting trace C6 on the sixth layer S6 through a fourteenth via hole V14, accordingly connected to the second output terminal 2b (cf. FIG. 34). One end T4B of the conducting trace C18 on the eighteenth layer S18 is connected to the sixth output terminal 4b, accordingly maintained at a fixed potential (preferably, a ground potential) (cf. FIG. 34).

Another magnetic material sheet S0 is put on the first layer S1 (cf. FIG. 37). Magnetic materials of all the layers are merged by adding heat to the entirety of the laminated magnetic material sheets. Thereby, like the coils running from the first layer S1 to the twelfth layer S12, the coil C13, C14, and C15 running from the thirteenth layer S13 to the fifteenth layer S15 magnetically couples to the coil C16, C17, and C18 running from the sixteenth layer S16 to the eighteenth layer S18, through the merged magnetic materials used as a core. In particular, both coils are wound in the same direction around the normal N, and accordingly, the thirteenth layer S13 through the fifteenth layer S15, that is, the fifth inductor L5 and the sixth inductor L6 form a second normal mode choke 4.

The normal mode choke 3 and the second normal mode choke 4 are arranged symmetrically with respect to the common mode choke 2 between the side of the first input terminal 1a and the second input terminal 1b, and the side of the first output terminal 2a and the second output terminal 2b in the filter circuit 1 according to Embodiment 5 of the present invention, like in the filter circuit according to Embodiment 4. Furthermore, both impedances of the normal mode choke 3 and the second normal mode choke 4 are sufficiently low for common mode signals, and sufficiently high for differential signals. Accordingly, common-mode noises received through the first input terminal 1a and the second input terminal 1b are reliably cut off from the first output terminal 2a and the second output terminal 2b. Conversely, common-mode noises received through the first output terminal 2a and the second output terminal 2b are reliably cut off from the first input terminal 1a and the second input terminal 1b. In addition, substantial common-mode noises are not reflected by the common mode choke 2 toward the first output terminal 2a and the second output terminal 2b, and toward the first input terminal 1a and the second input terminal 1b. Moreover, substantial common mode currents do not flow in the common mode choke 2, and thus, the core of the common mode choke 2 does not become magnetically saturated. Therefore, the filter circuit 1, which is served as a two-way common-mode noise filter, has a high degree of reliability. In particular, the core of the common mode choke 2 may have a low volume, and accordingly, the common mode choke 2 is allowed to be composed of the multilayer inductors (or, the thin film inductors) as described above.

Note that the number of the layers and the number of turns of the conducting traces may be different from those shown in FIG. 35. Furthermore, the shape of the coil may be a circle or another polygon, in contrast to the rectangle shown in FIGS. 35 and 36. However, it is desirable that the turn number and shape of the coil C1, C2, and C3 included in the first inductor L1 accurately matches with those of the coil C4, C5, and C6 included in the second inductor L2. Similarly, it is desirable that the turn number and shape of the coil C7, C8, and C9 included in the third inductor L3 accurately matches with those of the coil C10, C11, and C12 included in the fourth inductor L4, and the turn number and shape of the coil C13, C14, and C15 included in the fifth inductor L5 accurately matches with those of the coil C16, C17, and C18 included in the sixth inductor L6. Thereby, a high balance is maintained between the first input terminal 1a and the second input terminal 1b, and between the first output terminal 2a and the second output terminal 2b, and therefore, no distortions occur in the differential signals that penetrate the filter circuit 1.

Alternatively, the end T3A of the conducting trace C9 on the ninth layer S9 and the end T3B of the conducting trace C12 on the twelfth layer S12, in contrast to those shown in FIGS. 35 and 36, may be located at the same distance from the end T1A of the conducting trace C1 on the first layer S1 and the end T1B of the conducting trace C4 on the fourth layer S4 (see, for example, portions T3D and T3E shown by the alternate long and short dash lines in FIG. 36). Similarly, the end T4A of the conducting trace C15 on the fifteenth layer S15 and the end T4B of the conducting trace C18 on the eighteenth layer S18 may be located at the same distance from the end T2A of the conducting trace C3 on the third layer S3 and the end T2B of the conducting trace C6 on the sixth layer S6 (see, for example, portions T3D and T3E shown by the alternate long and short dash lines in FIG. 36). Thereby, a high balance is maintained between the first input terminal 1a and the second input terminal 1b, and between the first output terminal 2a and the second output terminal 2b, and therefore, no distortions occur in the differential signals that penetrate the filter circuit 1.

In the common mode choke 2, in contrast to that shown in FIGS. 35 and 37, the three layers S1, S2, and S3 that constitute the first inductor L1, and the three layers S4, S5, and S6 that constitute the second inductor L2, may be alternately laminated (cf. FIGS. 18, 19). Thereby, the conducting traces C1, C2, and C3 included in the first inductor L1 and the conducting traces C4, C5, and C6 included in the second inductor have equal spacing and equal parasitic capacitance that depends on the spacing, for example (cf. FIG. 19). As a result, the balance is further improved in lines for the differential signals included in the filter circuit 1. Accordingly, no distortion occurs in the differential signals that penetrate the filter circuit 1. In the normal mode choke 3, the three layers S7, S8, and S9 that constitute the third inductor L3, and the three layers S10, S11, and S12 that constitute the fourth inductor L4, may be alternately laminated (not shown in the figures), in a similar manner to that of the common mode choke 2. Furthermore, in the second normal mode choke 4, the three layers S13, S14, and S15 that constitute the fifth inductor L5, and the three layers S16, S17, and S18 that constitute the sixth inductor L6, may be alternately laminated (not shown in the figures).

The order of the laminated layers may be freely set among the six layers S1-S6 that constitute the common mode choke 2, among the six layers S7-S12 that constitute the normal mode choke 3, and among the six layers S13-S18 that constitute the second normal mode choke 4. A magnetic separation layer Ss may be inserted between two of the common mode choke 2, the normal mode choke 3, and the second normal mode choke 4, for example, between the sixth layer S6 and the seventh layer S7, or between the twelfth layer S12 and the thirteenth layer S13 (cf. FIG. 20). The magnetic separation layer Ss is similar to that according to Embodiment 1, and in particular, able to block magnetic fields, and thereby, magnetically separates the common mode choke 2 and the two normal mode chokes 3, 4. As a result, the common mode choke 2 and the two normal mode chokes 3, 4 do not interfere with each other, and accordingly, all of them have a higher degree of reliability. In order to reduce magnetic interference among the common mode choke 2 and the two normal mode chokes 3, 4, the three chokes 2, 3, and 4 may be formed in the separate regions on magnetic material sheets (cf. FIGS. 21, 22, and 23), in contrast to those described above.

In the equivalent circuit of the filter circuit 1 shown in FIG. 34, the third output terminal 3a and the fourth output terminal 3b are separated terminals, and the fifth output terminal 4a and the sixth output terminal 4b are separated terminals. Alternatively, a first common output terminal 3c may double as the third output terminal 3a and the fourth output terminal 3b, and a second common output terminal 4c may double as the fifth output terminal 4a and the sixth output terminal 4b (cf. FIG. 38). Thereby, the number of terminals of the filter circuit 1 is reduced, and accordingly, the circumference circuit design has a higher degree of flexibility. For example, the seventeenth via hole V17 connects a conducting trace C9A on the ninth layer S9 to a conducting trace C12A on the twelfth layer S12 (cf. FIG. 39), in contrast to the filter circuit 1 shown in FIGS. 35, 36, and 37. One end T3C of the conducting trace C12A on the twelfth layer S12 is connected to the first common output terminal 3c, and then maintained at a fixed potential (preferably, a ground potential). Here, the end T3C of the conducting trace C12A on the twelfth layer S12 is located at the same distance from the end T1A of the conducting trace C1 on the first layer S1 and the end T1B of the conducting trace C4 on the fourth layer S4 (cf. FIG. 40). Similarly, the eighteenth via hole V18 connects a conducting trace C15A on the fifteenth layer S15 to a conducting trace C18A on the eighteenth layer S18 (cf. FIG. 39). One end T4C of the conducting trace C18A on the eighteenth layer S18 is connected to the second common output terminal 4c, and then maintained at a fixed potential (preferably, a ground potential). Here, the end T4C of the conducting trace C18A on the eighteenth layer S18 is located at the same distance from the end T2A of the conducting trace C3 on the third layer S3 and the end T2B of the conducting trace C6 on the sixth layer S6 (cf. FIG. 40). A high balance is maintained between the first input terminal 1a and the second input terminal 1b, and between the first output terminal 2a and the second output terminal 2b, and therefore, no distortion occurs in the differential signals that penetrate the filter circuit 1.

### Embodiment 6

A differential transmission system according to Embodiment 6 of the present invention is preferably installed into an in-car LAN, like the system according to Embodiment 4. Embodiment 6 of the present invention differs from Embodiments 4, 5 in the way that a filter circuit 1 includes a terminator element. A description of components according to Embodiment 6 of the present invention that are similar to components according to Embodiment 4 or 5, can be found above in the description of Embodiment 4 or 5.

Terminator elements Z1, Z2, Z3, and Z4 are connected to either or both of two normal mode chokes 3 and 4 in the filter circuit 1 according to Embodiment 6 of the present invention (cf. FIGS. 41, 42, 43, and 44), in a manner similar to that in the filter circuit according to Embodiment 3. All the terminator elements Z1, Z2, Z3, and Z4 are impedance elements similar to the terminator elements Z1 and Z2 according to Embodiment 3. Accordingly, their details can be found above in the description of Embodiment 3.

When the two normal mode chokes 3, 4 are elements that are separated from the common mode choke 2, preferably, the first terminator element Z1 is connected between the third inductor L3 and the third output terminals 3a, the second terminator element Z2 is connected between the fourth inductor L4 and the fourth output terminal 3b, the third terminator element Z3 is connected between the fifth inductor L5 and the fifth output terminal 4a, and the fourth terminator element Z4 is connected between the sixth inductor L6 and the sixth output terminal 4b (cf. FIG. 41). Alternatively, the first terminator element Z1 may be connected between the first input terminal 1a and the third inductor L3, the second terminator element Z2 may be connected between the second input terminal 1b and the fourth inductor L4, the third terminator element Z3 may be connected between the fifth inductor L5 and the fifth output terminal 4a, and the fourth terminator element Z4 may be connected between the sixth inductor L6 and the sixth output terminal 4b (cf. parts shown by broken lines in FIG. 41). Note that one of either of the pair of the first and second terminator elements Z1 and Z2 or the pair of the third and fourth terminator elements Z3 and Z4 may be eliminated. Similar configuration are arranged when a common mode choke array 2C that includes three common mode chokes is used as a combination of the common mode choke 2 and the two normal mode chokes 3, 4 (cf. FIG. 42).

When the common mode choke 2 and the two normal mode chokes 3, 4 are constructed by multilayer inductors (or thin film inductors), like Embodiment 5 of the present invention, the first terminator element Z1 is connected between one end T3A of the third inductor L3 and the third output terminal 3a, the second terminator element Z2 is connected between one end T3B of the fourth inductor L4 and the fourth output terminal 3b, the third terminator element Z3 is connected between one end T4A of the fifth inductor L5 and the fifth output terminal 4a, and the fourth terminator element Z4 is connected between one end T4B of the sixth inductor L6 and the sixth output terminal 4b (cf. FIGS. 35, 43). Furthermore, when a first common output terminal 3c doubles as the third output terminal 3a and the fourth output terminal 3b, and a second common output terminal 4c doubles as the fifth output terminal 4a and the sixth output terminal 4b, the first terminator element Z1 and the second terminator element Z2 are combined into a single, first terminator element Z, which is connected between the first common output terminal 3c and a common end T3C of the third inductor L3 and the fourth inductor L4. In addition, the third terminator element Z3 and the fourth terminator element Z4 are combined into a single, second terminator element Za, which is connected between a common end T4C of the fifth inductor L5 and the sixth inductor L6 and the second common output terminal 4c (cf. FIGS. 39, 44).

For common mode signals received through the first input terminal 1a and the second input terminal 1b, or through the first output terminal 2a and the second output terminal 2b, the impedance of the common mode choke 2 is extremely high, and both impedances of the two normal mode chokes 3, 4 are extremely low. Accordingly, in the differential receiving device 10 (and, the differential transmitting and receiving device 30) shown in FIGS. 2 and 3, each impedance of the first terminator element Z1 and the second terminator element Z2 (in FIG. 44, the impedance of the first integrated terminator element Z) is adjusted to match the common mode impedance of the cable 40. Furthermore, the impedances of the third terminator element Z3 and the fourth terminator element Z4 (in FIG. 44, the impedance of the second integrated terminator element Za) are respectively adjusted to match the input impedance of the differential receiver 11 (31) and the common mode impedance of the differential line 12 (33). Thus, impedance matching for common mode signals is realized between the cable 40 and the filter circuit 1, and between the filter circuit 1 and the differential line 12 (33), with high precision, and then, the reflection of common-mode noises by the common mode choke 2 is further reduced. As a result, EMI radiations from the cable 40 and the differential line 12 (33) to the vicinity thereof are further reduced, and the differential receiver 11 (31) is more reliably protected from the reflected common-mode noises.

Similarly, in the differential transmitting device 20 shown in FIGS. 2 and 3, each impedance of the first terminator element Z1 and the second terminator element Z2 (in FIG. 44, the impedance of the first integrated terminator element Z) is adjusted to match the common mode impedance of the differential line 22. Furthermore, each impedance of the third terminator element Z3 and the fourth terminator element Z4 (in FIG. 44, the impedance of the second integrated terminator element Za) is adjusted to match the common mode impedance of the cable 40. Thus, impedance matching for common mode signals is realized between the differential line 22 and the filter circuit 1 and between the filter circuit 1 and the cable 40 with high precision, and then, the reflection of common-mode noises by the common mode choke 2 is further reduced. As a result, EMI radiations from the cable 40 and the differential line 22 to the surroundings are further reduced. In addition, common-mode noises are prevented from penetrating the LSI that includes the differential driver 32, and further from penetrating the previous stage circuits, and accordingly, the power potential and the ground potential reliably avoid fluctuations caused by the reflected common-mode noises.

### Embodiment 7

A differential transmission system according to Embodiment 7 of the present invention is preferably installed into mobile information apparatuses such as mobile phones (cf. FIG. 45). The mobile information apparatuses are equipped with various modules such as an image processing LSI M1 and a RF circuit M2. Those modules are connected to a CPU M3 through cables 41, thereby integratively controlled.

The mobile information apparatus, especially the mobile phone, uses the RF circuit M2 for communication with the outside. At that time, electromagnetic waves are radiated from the RF circuit M2 and the antenna AT. Those electromagnetic waves cause noises in the cables 41. In addition to the noises, noises sent out directly from the image processing LSI M1 and the CPU M3 to the cables 41 are radiated as electromagnetic waves in the surroundings of the cables 41, and produce other noises in other cables 41 and the antenna AT. When the image processing LSI M1 or the CPU M3 processes enormous amount of data such as image data that are generated by especially a camera module CA, it tends to provide noises to the RF circuit M2 and the antenna AT because its processing speed is close to the frequencies of the communication. Like this, both levels of EMI radiations and the following noises are high in the mobile information apparatus. In order to reduce adverse effects of those noises on the circuits M1, M2, and M3, or EMIs, the communication through the cables 41 in the mobile information apparatus is generally performed in differential transmission schemes.

Like the ECUs, etc., shown in FIGS. 2 and 3, the image processing LSI M1 includes a differential transmitting device 20 as a communication port, and the CPU M3 includes a differential receiving device 10 as a communication port (cf. FIG. 46). Alternatively, a differential transmitting and receiving device 30 shown in FIGS. 2 and 3 may be included as each of their communication ports. These communication ports are connected to each other through the cables 41, and then constitute a differential transmission system. The cable 41 includes two differential lines. Signals propagating each differential line have opposite phases. Preferably, a shielded twist pair cable is used as the cable 41, or alternatively, a unshielded twist pair cable, a flat cable, or a flexible cable may be used. Especially in a folding mobile phone, the cables 41 may connect between circuits across a hinge H (cf. FIG. 45).

Both the differential receiving device 10 and the differential transmitting device 20 have components similar to those according to Embodiment 1 (cf. FIGS. 2, 3, and 46), and in particular, both include the filter circuits 1 according to the present invention. Here, the filter circuit 1 may be similar to that according to any of the above-described Embodiments 1-6. Any of the filter circuits 1 eliminates substantially all common-mode noises from differential signals propagating through the cable 41, and allows substantially all normal mode components of the differential signals to penetrate completely, while it is completely absorbed substantially all common-mode noises without reflecting them. As a result, EMI radiations from the cable 41 and the differential lines 12, 22 to the surroundings are reduced, and the differential receiver 11 and the differential driver 21 are reliably protected from the reflected common-mode noises. Furthermore, common mode currents do not flow in the core of the common mode choke, and thus, the core of the common mode choke does not become magnetically saturated. Accordingly, the filter circuit 1 has a high degree of reliability. In addition, the core of the common mode choke may have a low volume, and therefore, the filter circuit 1 is easy to miniaturize, thereby having an advantage in the installation thereof in a mobile information apparatus.

More preferably, terminator elements are connected to the differential lines 12 and 22 in the differential receiving device 10 and the differential transmitting device 20, in a manner similar to that of the devices according to Embodiment 1 (cf. FIGS. 4, 5). Since the filter circuit 1 has a low impedance for differential signals, the differential impedances of the differential lines 12, 22 and the impedances of the terminator elements are each adjusted to match the differential impedance of the cable 41. This results no substantial distortion and attenuation in the differential signals. In addition, the impedance matching adds no severe constraints to the layout of the differential line 12, 22, and thus, both the differential receiving device 10 and the differential transmitting device 20 have a high degree of flexibility in circuit design.

A system that can equip with the differential transmission system according to the present invention is not limited to an in-car LAN like Embodiments 1-6 or a mobile information apparatus like Embodiment 7. The differential transmission system according to the present invention can be used in a general electronic appliance that uses a serial interface such as USB, IEEE 1394, LVDS, DVI, HDMI, serial ATA, and PCI express. This is self-evident for persons skilled in the art, based on the above-described Embodiments.

### Embodiment 8

A power supply device according to Embodiment 8 of the present invention is preferably installed in an electronic device (cf. FIG. 47). Here, the electronic device DV is preferably an information processing appliance such as a personal computer, a mobile phone, and a FAX machine. Alternatively, the power supply device may be a feeding device that provides electric power to other circuits in a differential transmission scheme. The power supply device 50 is connected to an external AC power supply AC such as a commercial AC power supply, through a plug PL and a power line 42. The power line 42 includes two differential lines. Voltages/currents have opposite phases between the differential lines. Note that the power supply device may be built into the plug PL.

The power supply device 50 comprises a filter circuit 1 according to the present invention and a switching power supply 51. The filter circuit 1 is connected to the power line 42, and then, it eliminates substantially all common-mode noises from the power supply line 42, and at the same time, allows substantially all electric power (differential signals) supplied from the external AC power supply AC to penetrate completely. The switching power supply 51 is an electric power converter, and preferably receives AC voltage from the external AC power supply AC through the filter circuit 1, and then, converts the AC voltage into predetermined DC voltages Vdd and Vss. Alternatively, the switching power supply 51 may improve the power factor of electric power supplied from the AC power supply AC. Furthermore, the switching power supply 51 may provide electric power to other circuits in a differential transmission scheme. When the power supply device 50 is used in power line communications (PLC), a PLC modem may be connected to the filter circuit 1, instead of the switching power supply 51.

The filter circuit 1 may be one according to any of the above-described Embodiments 1-6. Thereby, substantially all common-mode noises are completely absorbed by the filter circuit 1, without being reflected by it. As a result, EMI radiations from the power line 42 and internal conducting paths to the surroundings are reduced, and then, circuits inside the switching power supply 51 and the electronic device DV are reliably protected from the reflected common-mode noises. When PLC is performed, its communications quality is improved. Furthermore, common mode currents do not flow in the core of the common mode choke, and thus, the core of the common mode choke does not become magnetically saturated. Accordingly, the filter circuit 1 has a high degree of reliability. In addition, the core of the common mode choke may have a low volume, and therefore, the filter circuit 1 is easy to miniaturize, thereby having an advantage in the miniaturization of the power supply device DV.

### INDUSTRIAL APPLICABILITY

The present invention relates to a filter circuit installed in a differential transmission system and a power supply device, and eliminates common-mode noises from differential signals, by using a combination of a common mode choke and a normal mode choke, as described above. Thus, the present invention obviously has industrial applicability.

What is claimed is:

1. A filter circuit comprising:
a first input terminal and a second input terminal;
a first output terminal, a second output terminal, a third output terminal, and a fourth output terminal;
a common mode choke including
a first inductor that is connected between the first input terminal and the first output terminal, and
a second inductor that is magnetically coupled to the first inductor and connected between the second input terminal and the second output terminal in the same polarity as the polarity of the first inductor; and
a normal mode choke including
a third inductor that is connected between the first input terminal and the third output terminal, and
a fourth inductor that is magnetically coupled to the third inductor and connected between the second input terminal and the fourth output terminal in the polarity opposite to the polarity of the third inductor.

2. The filter circuit according to claim 1 wherein the common mode choke and the normal mode choke are placed in the same sealed package.

3. The filter circuit according to claim 1 wherein
the normal mode choke includes a core; and
the third and fourth inductors are two coils that are wound around the core one on top of the other, or separately from each other, in the polarities where the magnetic fluxes induced by common mode currents cancel each other out.

4. The filter circuit according to claim 1 wherein
the first to fourth inductors are multilayer inductors or thin film inductors that include laminated sheets of magnetic substances whose surfaces have a predetermined conductor pattern,
the first and second inductors are stacked one on top of the other, and
the third and fourth inductors are stacked one on top of the other.

5. The filter circuit according to claim 4 wherein
the common mode choke and the normal mode choke are stacked one on top of the other, and
the filter circuit further comprises a magnetic separation layer placed between the common mode choke and the normal mode choke.

6. The filter circuit according to claim 5 wherein the magnetic separation layer includes a conductor that is maintained at a constant potential.

7. The filter circuit according to claim 1 further comprising
a first impedance element that is connected either between the third inductor and the third output terminal, or between the first input terminal and the third inductor, or both, and
a second impedance element that is connected either between the fourth inductor and the fourth output terminal, or between the second input terminal and the fourth inductor, or both.

8. The filter circuit according to claim 1 further comprising
a fifth output terminal and a sixth output terminal; and
a second normal mode choke including
a fifth inductor that is connected between the first output terminal and the fifth output terminal, and
a sixth inductor that is magnetically coupled to the fifth inductor and connected between the second output terminal and the sixth output terminal in the polarity opposite to the polarity of the fifth inductor.

9. The filter circuit according to claim 8 wherein the common mode choke, the normal mode choke, and the second normal mode choke are placed in the same sealed package.

10. The filter circuit according to claim 8 wherein
the second normal mode choke includes a core; and
the fifth and sixth inductors are two coils that are wound around the core one on top of the other, or separately from each other, in the polarities where the magnetic fluxes induced by common mode currents cancel each other out.

11. The filter circuit according to claim 8 wherein
the first to sixth inductors are multilayer inductors or thin film inductors that include laminated sheets of magnetic substances whose surfaces have a predetermined conductor pattern,
the first and second inductors are stacked one on top of the other,
the third and fourth inductors are stacked one on top of the other, and
the fifth and sixth inductors are stacked one on top of the other.

12. The filter circuit according to claim 11 wherein
at least two of the common mode choke, the normal mode choke, and the second normal mode choke are stacked one on top of the other, and
the filter circuit further comprises a magnetic separation layer placed between the stacked chokes.

13. The filter circuit according to claim 12 wherein the magnetic separation layer includes a conductor that is maintained at a constant potential.

14. The filter circuit according to claim 8 further comprising
a third impedance element that is connected either between the fifth inductor and the fifth output terminal, or between the first output terminal and the fifth inductor, or both, and
a fourth impedance element that is connected either between the sixth inductor and the sixth output terminal, or between the first output terminal and the sixth inductor, or both.

15. A differential receiving device comprising
a filter circuit comprising:
a first input terminal and a second input terminal that are connected to external differential transmit paths;
a first output terminal and a second output terminal;
a third output terminal and a fourth output terminal that are maintained at constant potentials;
a common mode choke including
a first inductor that is connected between the first input terminal and the first output terminal, and
a second inductor that is magnetically coupled to the first inductor and connected between the second input terminal and the second output terminal in the same polarity as the polarity of the first inductor; and
a normal mode choke including
a third inductor that is connected between the first input terminal and the third output terminal, and
a fourth inductor that is magnetically coupled to the third inductor and connected between the second input terminal and the fourth output terminal in the polarity opposite to the polarity of the third inductor;
and
a differential receiver comprising a pair of input terminals that are connected to the first and second output terminals of the filter circuit, respectively.

16. The differential receiving device according to claim 15 further comprising a terminator element connected between each of the input terminals of the differential receiver and an external fixed-potential terminal.

17. The differential receiving device according to claim 15 further comprising a terminator element connected between the input terminals of the differential receiver.

18. A differential transmitting device comprising
a filter circuit comprising:
a first input terminal and a second input terminal;
a first output terminal and a second output terminal that are connected to external differential transmit paths;
a third output terminal and a fourth output terminal that are maintained at constant potentials;
a common mode choke including
a first inductor that is connected between the first input terminal and the first output terminal, and
a second inductor that is magnetically coupled to the first inductor and connected between the second input terminal and the second output terminal in the same polarity as the polarity of the first inductor; and
a normal mode choke including
a third inductor that is connected between the first input terminal and the third output terminal, and
a fourth inductor that is magnetically coupled to the third inductor and connected between the second input terminal and the fourth output terminal in the polarity opposite to the polarity of the third inductor;
and
a differential driver comprising a pair of output terminals that are connected to the first and second input terminals of the filter circuit, respectively.

19. A differential transmitting and receiving device comprising
a filter circuit comprising:
a first input/output terminal and a second input/output terminal;
a third input/output terminal and a fourth input/output terminal that are connected to external differential transmit paths;
first through fourth output terminals that are maintained at constant potentials;
a common mode choke including
a first inductor that is connected between the first and third input/output terminals, and
a second inductor that is magnetically coupled to the first inductor and connected between the second and fourth input/output terminals in the same polarity as the polarity of the first inductor;
a first normal mode choke including
a third inductor that is connected between the first input/output terminal and the first output terminal, and
a fourth inductor that is magnetically coupled to the third inductor and connected between the second and fourth input/output terminals in the polarity opposite to the polarity of the third inductor; and
a second normal mode choke including
a fifth inductor that is connected between the third input/output terminal and the third output terminal, and
a sixth inductor that is magnetically coupled to the fifth inductor and connected between the fourth input/output terminal and the fourth output terminal in the polarity opposite to the polarity of the fifth inductor;
a differential receiver comprising a pair of input terminals that are connected to the first and second input/output terminals of the filter circuit, respectively;
and
a differential driver comprising a pair of output terminals that are connected to the first and second input/output terminals of the filter circuit, respectively.

20. A differential transmission system comprising:
a differential transmitting device comprising
a first filter circuit comprising
a first input terminal and a second input terminal,
a first output terminal and a second output terminal,
a third output terminal and a fourth output terminal that are maintained at constant potentials,
a first common mode choke including
a first inductor that is connected between the first input terminal and the first output terminal, and
a second inductor that is magnetically coupled to the first inductor and connected between the second input terminal and the second output terminal in the same polarity as the polarity of the first inductor, and
a first normal mode choke including
a third inductor that is connected between the first input terminal and the third output terminal, and
a fourth inductor that is magnetically coupled to the third inductor and connected between the second input terminal and the fourth output terminal in the polarity opposite to the polarity of the third inductor,
and
a differential driver comprising a pair of output terminals that are connected to the first and second input terminals of the first filter circuit, respectively;
a differential receiving device comprising
a second filter circuit comprising
a third input terminal and a fourth input terminal,
a fifth output terminal and a sixth output terminal,
a seventh output terminal and an eighth output terminal that are maintained at constant potentials,
a second common mode choke including
a fifth inductor that is connected between the third input terminal and the fifth output terminal, and
a sixth inductor that is magnetically coupled to the fifth inductor and connected between the fourth input terminal and the sixth output terminal in the same polarity as the polarity of the fifth inductor, and
a second normal mode choke including
a seventh inductor that is connected between the third input terminal and the seventh output terminal, and
an eighth inductor that is magnetically coupled to the seventh inductor and connected between the fourth input terminal and the eighth output terminal in the polarity opposite to the polarity of the seventh inductor,
and
a differential receiver comprising a pair of input terminals that are connected to the third and fourth output terminals of the second filter circuit, respectively;
and
differential transmission paths connecting the first and second output terminals to the third and fourth output terminals, respectively.

21. A differential transmission system comprising:
two differential transmitting and receiving devices each comprising
a filter circuit comprising
a first input/output terminal and a second input/output terminal,
a third input/output terminal and a fourth input/output terminal,
first through fourth output terminals that are maintained at constant potentials,
a common mode choke including
a first inductor that is connected between the first and third input/output terminals, and
a second inductor that is magnetically coupled to the first inductor and connected between the second and fourth input/output terminals in the same polarity as the polarity of the first inductor,
a first normal mode choke including
a third inductor that is connected between the first input/output terminal and the first output terminal, and
a fourth inductor that is magnetically coupled to the third inductor and connected between the second and fourth input/output terminals in the polarity opposite to the polarity of the third inductor, and
a second normal mode choke including
a fifth inductor that is connected between the third input/output terminal and the third output terminal, and
a sixth inductor that is magnetically coupled to the fifth inductor and connected between the fourth input/output terminal and the fourth output terminal in the polarity opposite to the polarity of the fifth inductor,
a differential receiver comprising a pair of input terminals that are connected to the first and second input/output terminals of the filter circuit, respectively,
and
a differential driver comprising a pair of output terminals that are connected to the first and second input/output terminals of the filter circuit, respectively;
and
differential transmission paths, between the two differential transmitting and receiving devices, connecting the third input/output terminals to each other and connecting the fourth input/output terminals to each other.

22. A power supply comprising
a filter circuit comprising:
a first input terminal and a second input terminal that are connected to external power lines;
a first output terminal and a second output terminal;
a third output terminal and a fourth output terminal that are maintained at constant potentials;
a common mode choke including
a first inductor that is connected between the first input terminal and the first output terminal, and
a second inductor that is magnetically coupled to the first inductor and connected between the second input terminal and the second output terminal in the same polarity as the polarity of the first inductor; and
a normal mode choke including
a third inductor that is connected between the first input terminal and the third output terminal, and
a fourth inductor that is magnetically coupled to the third inductor and connected between the second input terminal and the fourth output terminal in the polarity opposite to the polarity of the third inductor;
and
a power transducer comprising a pair of input terminals that are connected to the first and second output terminals of the filter circuit, respectively.
